(19) United States
(12) Patent Application Publication
(10) Pub. No.: US 2025/0342894 A1
(43) Pub. Date: Nov. 6, 2025

(54) METHODS, DEVICES, AND SYSTEMS FOR ANOMALY DETECTION FOR NON-VOLATILE MEMORY DEVICE PROGRAMMING

(71) Applicant: Samsung Electronics Co., Ltd., Suwon-si (KR)

(72) Inventors: Amit BERMAN, Binyamina (IL); Evgeny BLAICHMAN, Tel-Aviv (IL); Jonathan ZEDAKA, Jerusalem (IL); Karen MICHAELI, Tel-Aviv (IL)

(73) Assignee: Samsung Electronics Co., Ltd., Suwon-si (KR)

(21) Appl. No.: 18/653,446

(22) Filed: May 2, 2024

(51) Int. Cl. G11C 16/34; G11C 16/10; G11C 29/52

(52) U.S. Cl. CPC G11C 16/3459; G11C 16/102; G11C 29/52

(57) ABSTRACT

An iterative programming operation having at least 1 to n-th programming stages may be performed to program a non-volatile memory device having memory cells connected through a word line. The n-th programming stage may apply an n-th program voltage to the word line and generate an n-th verification result indicating a number of the plurality of memory cells having a threshold voltage at least meeting a particular verification voltage at the n-th programming stage. An n-th model stage of an iterative model may be performed to utilize the n-th verification result and n-th historical data associated with at least an (n−1)-th programming stage to determine an n-th probability. A programming anomaly may be determined based on the n-th probability at least meeting an n-th threshold probability. In response to the programming anomaly, the iterative programming operation may be stopped prior to completing a final programming stage thereof.

### BACKGROUND

### 1. Technical Field

The present inventive concepts relate to semiconductor memory devices, and more particularly to non-volatile memory devices, programming methods thereof and detection of anomalies in such programming methods.

### 2. Description of Related Art

Semiconductor memory device types include volatile memory devices and non-volatile memory devices.

Non-volatile memory devices retain stored data even while the power supply is cut off. Therefore, non-volatile memory devices are used to save contents that must be retained, regardless of whether power is supplied or not. Examples of non-volatile memory devices include a Read-only Memory (ROM), a Programmable Read-only Memory (PROM), an Erasable Programmable Read-only Memory (EPROM), an Electrically Erasable Programmable Read-only Memory (EEPROM), a flash memory, Phase-change Random Access Memory (PRAM), a Magnetic Random Access Memory (MRAM), a Resistive Random Access Memory (RRAM), Ferroelectric Random Access Memory (FRAM), and the like.

Flash memory, a type of non-volatile memory, has a function of erasing data of cells collectively, and is widely used in computer systems and memory cards.

Flash memory may be a NOR-type or a NAND-type, depending on connections between memory cell transistors and to a bit line. The NOR-type flash memory takes a form of two or more memory cell transistors connected in parallel to one bit line, stores data by using a Channel Hot Electron method, and erases data by using a Fowler-Nordheim tunneling. On the other hand, the NAND-type flash memory takes a form of two or more cell transistors connected in series to one bit line, and stores and erases data by using the Fowler-Nordheim tunneling. The NOR-type flash memory is not suitable for high integration due to consumption of large amount of current, however it is advantageous in that it can adapt easily to acceleration of its operation speed. On the other hand, the NAND-type flash memory may be more highly integrated as it uses less cell current compared to the NOR-type flash memory.

### SUMMARY

Some example embodiments of the inventive concepts described herein relate to methods, and devices and systems configured to implement same, that enable detection of programming anomalies in an iterative (e.g., multi-stage) programming operation to program a non-volatile memory device, where an anomaly may be determined based on performing a given n-th programming stage (e.g., an n-th program loop) of an iterative programming operation having a sequence of at least 1 to n-th programming stages, which may be prior to completing a final programming stage of the programming operation.

In some example embodiments, a method (e.g., an anomaly detection operation) may utilize an iterative model, including for example a recurrent neural network (RNN), that, at a given n-th model stage (e.g., model loop, iterative model loop, etc.), processes data from a given n-th programming stage (e.g., program loop, iterative program loop, etc.) in addition to data associated with one or more prior programming stages (e.g., an (n−1)-th programming stage) to determine a probability value that is associated with a likelihood of occurrence of at least one programming anomaly in the iterative programming operation. Programming anomaly occurrence in the 1 to n-th programming stages of the iterative programming operation may be determined based on processing the probability value, for example comparing the probability value to a threshold value and determining occurrence of at least one programming anomaly in response to a determination that the probability value at least meets the threshold value.

The iterative model may operate each n-th model stage based on a corresponding n-th programming stage of the iterative programming operation. Each n-th model stage may be performed at least partially concurrently with performing one or more stages of the programming operation (e.g., an (n+1)-th programming stage), thereby enabling the programming anomaly detection to be performed with minimized or no additional latency in the iterative programming operation, thereby improving anomaly detection capabilities without loss of programming operation performance of a device implementing the iterative programming operation.

As a result, a programming anomaly in the iterative programming operation may be detected during the iterative programming operation (e.g., prior to completion of the final programming stage of the programming operation in example embodiments where the iterative programming operation includes a predetermined “N” programming stages or program loops), which may enable “early” detection of programming anomalies and thus early recovery action thereto to recover from the programming anomalies to be initiated without waiting until completion of the final programming stage. Such early recovery action may include early termination of the iterative programming operation prior to completion of the final stage thereof. As a result, recovery from a programming anomaly may occur more quickly than schemes that perform anomaly detection upon completion of the final programming stage, thereby improving the speed at which an iterative programming operation may be successfully completed at a non-volatile memory device, thereby improving the functionality of a device implementing the iterative programming operation.

The anomaly detection operation may enable detection of a programming anomaly based upon whether the verification result data of a given programming stage, and further based on historical data associated with one or more preceding stages, is determined to be associated with at least a threshold likelihood of anomaly occurrence/absence. Anomaly detection may thus be based on a determination of whether the verification result data for one or more stages is sufficiently unusual, or improbable, to indicate that the verification result data for one or more stages indicates anomaly occurrence (e.g., the probability value at least meets a threshold probability value associated with programming anomaly occurrence).

Because anomaly detection may be based upon determining whether the verification result data for one or more stages is sufficiently “unusual” or “improbable” instead of, for example, determining whether a low number of cells have a threshold voltage reaching a verification voltage (e.g., an underprogramming anomaly), the anomaly detection process may enable various additional types of programming anomalies to be detected. For example the anomaly detection process may enable detection of an “overprogramming” anomaly where one or more memory cells are programmed to a threshold voltage beyond an expected range of threshold voltages for the target verification voltage. Thus, performing the anomaly detection operation may enable more versatile anomaly detection, thereby improving reliability of a device implementing the iterative programming operation and the anomaly detection operation.

According to some example embodiments, a method may include performing an iterative programming operation to program a non-volatile memory device having at least a plurality of memory cells. The plurality of memory cells may be connected through a word line, the iterative programming operation having a sequence of at least 1 to n-th programming stages, n being a positive integer that is greater than 1. The n-th programming stage may include applying an n-th program voltage to the word line connected to the plurality of memory cells, and performing a verification operation associated with a particular verification voltage on the plurality of memory cells to generate an n-th verification result value. The n-th verification result value may indicate a number of memory cells of the plurality of memory cells having a threshold voltage that is equal to or greater than the particular verification voltage at the n-th programming stage. The method may include performing at least an n-th stage of an iterative model that utilizes the n-th verification result value and n-th historical data associated with at least an (n−1)-th programming stage of the iterative programming operation to determine an n-th probability value indicating a probability associated with occurrence of at least one programming anomaly in the 1 to n-th stages of the iterative programming operation.

According to some example embodiments, a computer-implemented method may be performed to train a neural network to determine a probability associated with an occurrence of at least one programming anomaly in an iterative programming operation that programs a non-volatile memory device having a plurality of memory cells connected through a word line. The method of training the neural network may include receiving measurement data based on performing one or more sample iterative programming operations having a sequence of a plurality of stages to program one or more sample non-volatile memory devices. The measurement data may include, for each sample iterative programming operation performed on each sample non-volatile memory device, a sequence of sample verification result values that each indicate a number of memory cells of the sample non-volatile device having a threshold voltage that is equal to or greater than a particular verification voltage at a particular programming stage of the sample iterative programming operation. Each sample iterative programming operation of the one or more sample iterative programming operations may not include any programming anomalies. The method of training the neural network may include training the neural network as an iterative model using the measurement data as a training input to the neural network, such that the neural network is trained based on the measurement data to determine a probability associated with occurrence of at least one programming anomaly in a sequence of 1 to n-th stages of the iterative programming operation based on both an n-th verification result value indicating a number of memory cells of the plurality of memory cells having a threshold voltage that is equal to or greater than a particular verification voltage at the n-th programming stage, and n-th historical data associated with at least an (n−1)-th programming stage of the iterative programming operation.

According to some example embodiments, a storage device may include a memory storing a program of instructions, and a processor. The processor may be configured to execute the program of instructions to perform an iterative programming operation to program a non-volatile memory device having at least a plurality of memory cells, where the plurality of memory cells are connected through a word line. The iterative programming operation may have a sequence of at least 1 to n-th programming stages, n being a positive integer that is greater than 1. The n-th programming stage may include applying an n-th program voltage to the word line connected to the plurality of memory cells, and performing a verification operation associated with a particular verification voltage on the plurality of memory cells to generate an n-th verification result value, the n-th verification result value indicating a number of memory cells of the plurality of memory cells having a threshold voltage that is equal to or greater than the particular verification voltage at the n-th programming stage. The processor may be configured to execute the program of instructions to perform at least an n-th stage of an iterative model that utilizes the n-th verification result value and n-th historical data associated with at least an (n−1)-th programming stage of the iterative programming operation to determine an n-th probability value indicating a probability associated with occurrence of at least one programming anomaly in the 1 to n-th stages of the iterative programming operation.

According to some example embodiments, a storage device may include a memory storing a program of instructions, and a processor. The processor may be configured to execute the program of instructions to perform a method of training a neural network to determine a probability associated with an occurrence of at least one programming anomaly in an iterative programming operation that programs a non-volatile memory device having a plurality of memory cells connected through a word line. The method of training the neural network may include receiving measurement data based on performing one or more sample iterative programming operations having a sequence of a plurality of stages to program one or more sample non-volatile memory devices. The measurement data may include, for each sample iterative programming operation performed on each sample non-volatile memory device, a sequence of sample verification result values that each indicate a number of memory cells of the sample non-volatile device having a threshold voltage that is equal to or greater than a particular verification voltage at a particular programming stage of the sample iterative programming operation. Each sample iterative programming operation of the one or more sample iterative programming operations may not include any programming anomalies. The method of training the neural network may include training the neural network as an iterative model using the measurement data as a training input to the neural network, such that the neural network is trained based on the measurement data to determine a probability associated with occurrence of at least one programming anomaly in a sequence of 1 to n-th stages of the iterative programming operation based on both an n-th verification result value indicating a number of memory cells of the plurality of memory cells having a threshold voltage that is equal to or greater than a particular verification voltage at the n-th programming stage, and n-th historical data associated with at least an (n−1)-th programming stage of the iterative programming operation.

According to some example embodiments, a non-transitory computer-readable storage medium may have a computer program recorded thereon. The computer program, when executed by at least one processor, may be configured to cause the at least one processor to perform a method that includes performing an iterative programming operation to program a non-volatile memory device having at least a plurality of memory cells, where the plurality of memory cells are connected through a word line, the iterative programming operation having a sequence of at least 1 to n-th programming stages, n being a positive integer that is greater than 1. The n-th programming stage may include applying an n-th program voltage to the word line connected to the plurality of memory cells, and performing a verification operation associated with a particular verification voltage on the plurality of memory cells to generate an n-th verification result value, the n-th verification result value indicating a number of memory cells of the plurality of memory cells having a threshold voltage that is equal to or greater than the particular verification voltage at the n-th programming stage. The method may include performing at least an n-th stage of an iterative model that utilizes the n-th verification result value and n-th historical data associated with at least an (n−1)-th programming stage of the iterative programming operation to determine an n-th probability value indicating a probability associated with occurrence of at least one programming anomaly in the 1 to n-th stages of the iterative programming operation.

According to some example embodiments, a non-transitory computer-readable storage medium may have a computer program recorded thereon. The computer program, when executed by at least one processor, may be configured to cause the at least one processor to perform a method of training a neural network to determine a probability associated with an occurrence of at least one programming anomaly in an iterative programming operation that programs a non-volatile memory device having a plurality of memory cells connected through a word line. The method of training the neural network may include receiving measurement data based on performing one or more sample iterative programming operations having a sequence of a plurality of stages to program one or more sample non-volatile memory devices. The measurement data may include, for each sample iterative programming operation performed on each sample non-volatile memory device, a sequence of sample verification result values that each indicate a number of memory cells of the sample non-volatile device having a threshold voltage that is equal to or greater than a particular verification voltage at a particular programming stage of the sample iterative programming operation. Each sample iterative programming operation of the one or more sample iterative programming operations may not include any programming anomalies. The method of training the neural network may include training the neural network as an iterative model using the measurement data as a training input to the neural network, such that the neural network is trained based on the measurement data to determine a probability associated with occurrence of at least one programming anomaly in a sequence of 1 to n-th stages of the iterative programming operation based on both an n-th verification result value indicating a number of memory cells of the plurality of memory cells having a threshold voltage that is equal to or greater than a particular verification voltage at the n-th programming stage, and n-th historical data associated with at least an (n−1)-th programming stage of the iterative programming operation.

### BRIEF DESCRIPTION OF THE DRAWINGS

The above and other objects and features of the inventive concepts will become apparent by describing in detail some example embodiments thereof with reference to the accompanying drawings.

FIG. 1 is a block diagram of a system including at least one storage device, according to some example embodiments.

FIG. 2 is a block diagram of a storage device according to some example embodiments.

FIG. 3 is a block diagram of a storage device according to some example embodiments.

FIG. 4 is a block diagram of a memory device, according to some example embodiments.

FIG. 5A is a diagram illustrating a first memory block of a plurality of memory blocks included in a memory cell array in FIG. 4, according to some example embodiments.

FIG. 5B is a diagram illustrating a memory device according to some example embodiments.

FIG. 6 is a distribution diagram for describing an iterative programming operation to program a non-volatile memory device, according to some example embodiments.

FIG. 7 is a timing diagram for describing an iterative programming operation to program a non-volatile memory device, according to some example embodiments.

FIG. 8 illustrates measured programming rates of a plurality of iterative programming operations performed on a nonvolatile memory device, according to some example embodiments.

FIG. 9 illustrates a network structure of a recurrent neural network (RNN) of an iterative model of an iterative anomaly detection program, according to some example embodiments.

FIG. 10A is a flowchart illustrating a method of performing an iterative programming operation to program a non-volatile memory device having at least a plurality of memory cells, according to some example embodiments.

FIG. 10B is a flowchart illustrating a method of performing an iterative anomaly detection program corresponding to the iterative programming operation of FIG. 10A, according to some example embodiments.

FIG. 11 is a flowchart illustrating a method including an iterative programming operation and an iterative anomaly detection program, according to some example embodiments.

FIG. 12 is a distribution diagram of a faulty iterative programming operation to program a non-volatile memory device, according to some example embodiments.

FIG. 13 is a diagram illustrating a conditional probability distribution for verification result values of an n-th programming stage of an iterative programming operation, according to some example embodiments.

FIG. 14 is a distribution diagram of a faulty iterative programming operation to program a non-volatile memory device, according to some example embodiments.

FIG. 15 is a line graph illustrating a plurality of probability value sequences determined for separate, respective iterative programming operations, including standard and faulty iterative programming operations, according to some example embodiments.

FIG. 16 is an expanded view of region X in FIG. 15, according to some example embodiments.

FIG. 17 is a flowchart illustrating a computer-implemented method of training a neural network, according to some example embodiments.

FIG. 18 is a schematic block diagram of an electronic device according to some example embodiments.

### DETAILED DESCRIPTION

Below, some example embodiments of the inventive concepts will be described in detail and clearly to such an extent that one skilled in the art easily carries out the inventive concepts. In the following description, specific details such as detailed components and structures are merely provided to assist the overall understanding of some example embodiments of the inventive concepts. Therefore, it should be apparent to those skilled in the art that various changes and modifications of the example embodiments described herein may be made without departing from the scope and spirit of the inventive concepts. In addition, the descriptions of well-known functions and structures are omitted for clarity and brevity. In the following drawings or in the detailed description, components may be connected with any other components except for components illustrated in a drawing or described in the detailed description. The terms described in the specification are terms defined in consideration of the functions in the inventive concepts and are not limited to a specific function. The definitions of the terms should be determined based on the contents throughout the specification.

In the detailed description, components that are described with reference to the terms “driver”, “block”, “unit”, etc. will be implemented with software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, an inertial sensor, a micro electro mechanical system (MEMS), a passive element, or a combination thereof.

NAND memory devices strive to achieve high read throughput and low latency with low power consumption and low complexity. In order to achieve these goals, a minimal number of reads from the NAND is performed such that a single bit from the NAND channel is measured per bit that is written, which results in a hard decision (HD) binary channel.

Effective error correction codes (ECCs) for HD channels with good performance and low complexity are algebraic codes, such as Bose-Chaudhuri-Hocquenghem (BCH), Reed-Solomon (RS) and BCH-generalized concatenated codes (GCC).

If the HD decoding fails, it may be possible to read additional data from the NAND and receive additional soft information via a soft definition (SD) channel. This mode of operation is rare, and therefore, may be done with higher latency and complexity and requires high decoding capabilities.

For example, polar codes may be effective ECCs for SD channels with high decoding capabilities. However, polar codes require very high complexity and latency. In order to overcome the high complexity and latency, Polar-GCC codes can be used.

Some example embodiments of the present application include a construction of an ECC of the form of GCC with components of Polar-BCH sub-codes (e.g., a combination of polar codes and BCH codes) concatenated with RS codes. This family of codes, according to some example embodiments, exploits the benefits of BCH-GCC with low complexity decoders and excellent performance for HD channels, and also exploits the benefits of Polar-GCC with higher latency but good coverage for SD channels.

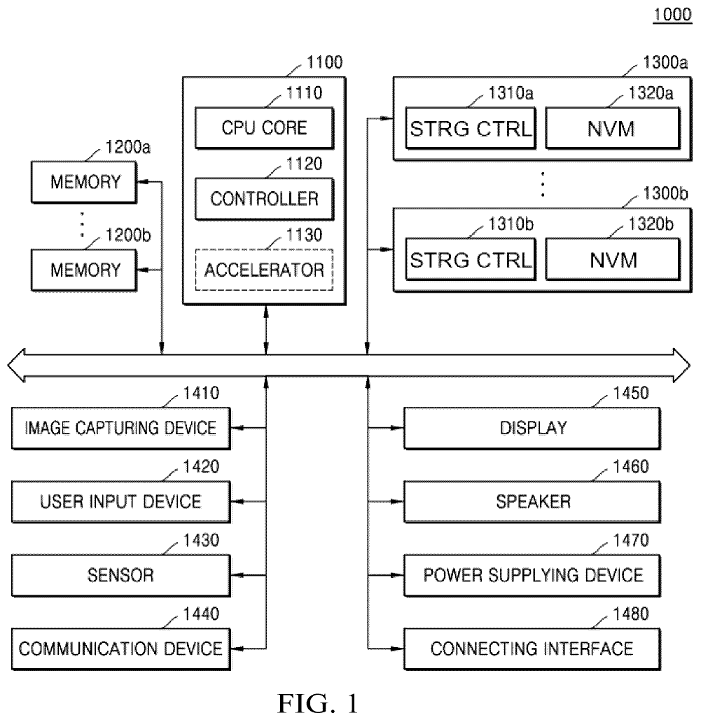

FIG. 1 is a block diagram of a system 1000 including at least one storage device, according to some example embodiments. The system 1000 of FIG. 1 may basically be a mobile system, such as a portable communication terminal (e.g., a mobile phone), a smartphone, a tablet personal computer (PC), a wearable device, a healthcare device, or an Internet of things (IoT) device. However, the system 1000 of FIG. 1 is not necessarily limited to the mobile system and may be a PC, a laptop computer, a server, a media player, or an automotive device (e.g., a navigation device). In some example embodiments, the system 1000 of FIG. 1 may be referred to as an electronic device.

Referring to FIG. 1, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480. While the system 1000 is shown to include multiple memories 1200a and 1200b, example embodiments are not limited thereto, and in some example embodiments the system 1000 may include a single memory (e.g., memory 1200a). While the system 1000 is shown to include multiple storage devices 1300a and 1300b, example embodiments are not limited thereto, and in some example embodiments the system 1000 may include a single storage device (e.g., storage device 1300a).

The main processor 1100 may control all operations of the system 1000, more specifically, operations of other components included in the system 1000. The main processor 1100 may be implemented as a general-purpose processor, a dedicated processor, or an application processor.

The main processor 1100 may include at least one CPU core 1110 and further include a controller 1120 configured to control the memories 1200a and 1200b and/or the storage devices 1300a and 1300b. In some embodiments, the main processor 1100 may further include an accelerator 1130, which is a dedicated circuit for a high-speed data operation, such as an artificial intelligence (AI) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100.

The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVMs (Non-Volatile Memories) 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied (e.g., is included), without being limited thereto.

The image capturing device 1410 may capture still images or moving images. The image capturing device 1410 may include a camera, a camcorder, and/or a webcam.

The user input device 1420 may receive various types of data input by a user of the system 1000 and include a touch pad, a keypad, a keyboard, a mouse, and/or a microphone.

The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem.

The display 1450 and the speaker 1460 may serve as output devices configured to respectively output visual information and auditory information to the user of the system 1000.

The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

It will be understood that the system 1000 may be configured to perform any methods, functionality, or the like according to any of the example embodiments, including an iterative programming operation performed to program a non-volatile memory device (e.g., at least one of NVM 1320a and/or NVM 1320b), an iterative anomaly detection program to perform an iterative model to at least determine probability values each indicating a probability associated with occurrence of at least one programming anomaly in one or more programming stages of the iterative programming operation, and in some example embodiments to determine whether at least one programming anomaly has occurred in the one or more programming stages of the iterative programming operation, for example based on determining that at least one probability value at least meets a corresponding threshold probability value. For example, the system 1000 may include a memory (e.g., memory 1200a and/or 1200b) storing a program of instructions and a processor (e.g., main processor 1100) configured to execute the program of instructions to implement any of the methods, functionalities of one or more devices, or the like according to any of the example embodiments, including the iterative anomaly detection program 900 including at least one iterative model 910 according to any of the example embodiments.

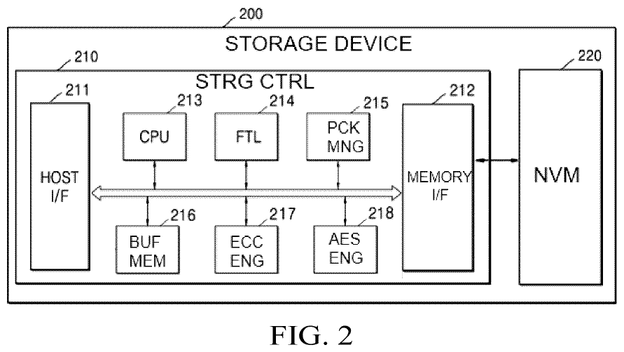

FIG. 2 is a block diagram of a storage device 200 according to some example embodiments.

The storage device 200 may include a storage controller 210 and a non-volatile memory device NVM 220. For example, the storage device 200 may include at least one of the storage devices 1300a and/or 1300b as shown in FIG. 1 such that the storage controller 210 may be at least one of the storage controllers 1310a and/or 1310b as shown in FIG. 1 and the NVM 220 may be at least one of the NVMs 1320a and/or 1320b as shown in FIG. 1.

The storage device 200 may include storage media configured to store data in response to requests from a host. As an example, the storage device 200 may include at least one of an SSD, an embedded memory, and a removable external memory. When the storage device 200 is an SSD, the storage device 200 may be a device that conforms to an NVMe standard. When the storage device 200 is an embedded memory or an external memory, the storage device 200 may be a device that conforms to a UFS standard or an eMMC standard. The storage device 200 may generate a packet according to an adopted standard protocol and transmit the packet.

When the NVM 220 of the storage device 200 includes a flash memory, the flash memory may include a 2D NAND memory array or a 3D (or vertical) NAND (VNAND) memory array. As another example, the storage device 200 may include various other kinds of NVMs. For example, the storage device 200 may include magnetic RAM (MRAM), spin-transfer torque MRAM, conductive bridging RAM (CBRAM), ferroelectric RAM (FRAM), PRAM, RRAM, and various other kinds of memories.

The storage controller 210 may include a host interface 211, a memory interface 212, and a CPU 213. Further, the storage controller 210 may further include a flash translation layer (FTL) 214, a packet manager 215, a buffer memory 216, an error correction code (ECC) engine 217, and an advanced encryption standard (AES) engine 218. The storage controller 210 may further include a working memory (not shown) in which the FTL 214 is loaded. The CPU 213 may execute the FTL 214 to control data write and read operations on the NVM 220.

The host interface 211 may transmit and receive packets to and from a host (not shown), for example the main processor 1100 shown in FIG. 1. A packet transmitted from the host to the host interface 211 may include a command or data to be written to the NVM 220. A packet transmitted from the host interface 211 to the host may include a response to the command or data read from the NVM 220. The memory interface 212 may transmit data to be written to the NVM 220 to the NVM 220 or receive data read from the NVM 220. The memory interface 212 may be configured to comply with a standard protocol, such as Toggle or open NAND flash interface (ONFI).

The FTL 214 may perform various functions, such as an address mapping operation, a wear-leveling operation, and a garbage collection operation. The address mapping operation may be an operation of converting a logical address received from a host into a physical address used to actually store data in the NVM 220. The wear-leveling operation may be a technique for preventing excessive deterioration of a specific block by allowing blocks of the NVM 220 to be uniformly used. As an example, the wear-leveling operation may be implemented using a firmware technique that balances erase counts of physical blocks. The garbage collection operation may be a technique for ensuring usable capacity in the NVM 220 by erasing an existing block after copying valid data of the existing block to a new block.

The packet manager 215 may generate a packet according to a protocol of an interface, which consents to a host, or parse various types of information from the packet received from a host. In addition, the buffer memory 216 may temporarily store data to be written to the NVM 220 or data to be read from the NVM 220. Although the buffer memory 216 may be a component included in the storage controller 210, the buffer memory 216 may be outside the storage controller 210.

The ECC engine 217 may perform error detection and correction operations on read data read from the NVM 220. More specifically, the ECC engine 217 may generate parity bits for write data to be written to the NVM 220, and the generated parity bits may be stored in the NVM 220 together with write data. During the reading of data from the NVM 220, the ECC engine 217 may correct an error in the read data by using the parity bits read from the NVM 220 along with the read data, and output error-corrected read data.

The AES engine 218 may perform at least one of an encryption operation or a decryption operation on data input to the storage controller 210 by using a symmetric-key algorithm.

In some example embodiments, the ECC engine 217 may include an ECC encoding circuit and an ECC decoding circuit. In response to an ECC control signal ECC_CON, which may include a signal indicating detection of an occurrence of at least one programming anomaly in an iterative programming operation performed on at least a selected word line of a memory cell array of the NVM 220, the ECC encoding circuit may generate parity bits ECCP[0:7] for write data WData[0:63] to be written to memory cells of the memory cell array of the NVM 220. The parity bits ECCP[0:7] may be stored in an ECC cell array of the ECC engine. According to some example embodiments, in response to the ECC control signal ECC_CON, the ECC encoding circuit 510 may generate parity bits ECCP[0:7] for write data WData[0:63] to be written to memory cells including a defective cell of a memory cell array of the NVM 220, where a defective cell may be determined to be one or a plurality of memory cells connected to a selected word line where an iterative programming operation performed on the selected word line is determined to have at least one programming anomaly.

In response to the ECC control signal ECC_CON, the ECC decoding circuit may correct error bit data by using read data RData[0:63] read from the memory cells of the memory cell array and parity bits ECCP[0:7] read from the ECC cell array and output error-corrected data Data[0:63]. According to some example embodiments, in response to the ECC control signal ECC_CON, the ECC decoding circuit may correct error bit data by using read data RData[0:63] read from memory cells including a defective cell of the memory cell array and parity bits ECCP[0:7] read from the ECC cell array, and output error-corrected data Data[0:63].

It will be understood that the storage device 200 may be configured to perform any methods, functionality, or the like according to any of the example embodiments, including an iterative programming operation performed to program a non-volatile memory device (e.g., NVM 220), an iterative anomaly detection program to perform an iterative model to at least determine probability values each indicating a probability associated with occurrence of at least one programming anomaly in one or more programming stages of the iterative programming operation, and in some example embodiments to determine whether at least one programming anomaly has occurred in the one or more programming stages of the iterative programming operation, for example based on determining that at least one probability value at least meets a corresponding threshold probability value. For example, the storage device 200 (e.g., the storage controller 210) may include a memory (e.g., a working memory of the storage controller 210 (not shown), which may include an SSD storage device) storing a program of instructions and a processor (e.g., CPU 213) configured to execute the program of instructions to implement any of the methods, functionalities of one or more devices, or the like according to any of the example embodiments, including the iterative anomaly detection program 900 including at least one iterative model 910 according to any of the example embodiments.

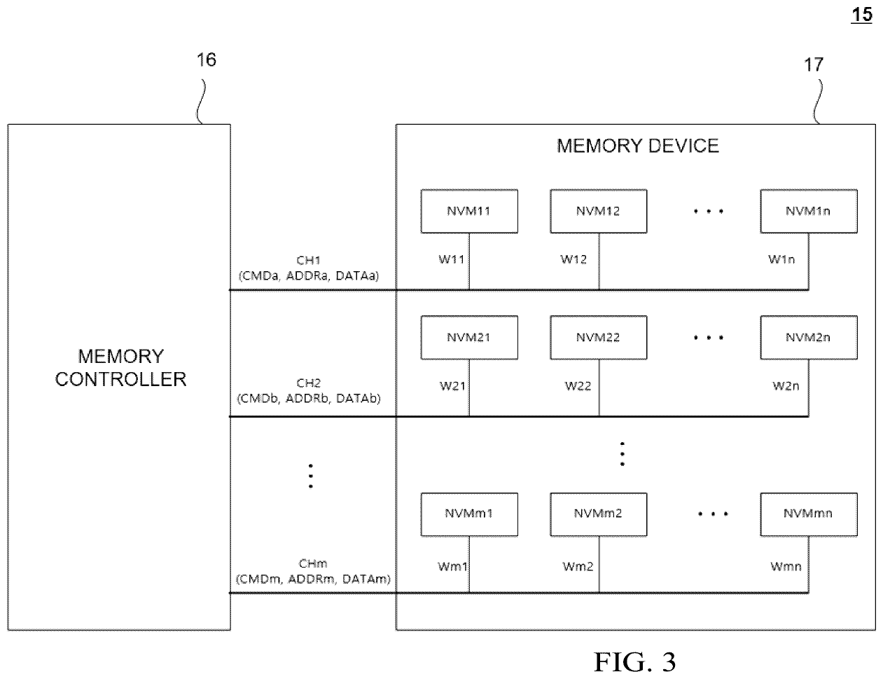

FIG. 3 is a block diagram of a storage device 15 according to some example embodiments.

Referring to FIG. 3, the storage device 15 may include a memory device 17 and a memory controller 16. For example, the storage device 15 may include at least one of the storage devices 1300a and/or 1300b as shown in FIG. 1 such that the memory controller may be at least one of the storage controllers 1310a and/or 1310b as shown in FIG. 1 and the memory device 17 may be at least one of the NVMs 1320a and/or 1320b as shown in FIG. 1. The storage device 15 may support a plurality of channels CH1 to CHm, and the memory device 17 may be connected to the memory controller 16 through the plurality of channels CH1 to CHm. For example, the storage device 15 may be implemented as a storage device, such as an SSD.

The memory device 17 may include a plurality of NVM devices NVM11 to NVMmn, wherein n and m may each independently a positive integer. Each of the NVM devices NVM11 to NVMmn may be connected to one of the plurality of channels CH1 to CHm through a way corresponding thereto. For instance, the NVM devices NVM11 to NVMIn may be connected to a first channel CH1 through ways W11 to Win, and the NVM devices NVM21 to NVM2n may be connected to a second channel CH2 through ways W21 to W2n. In some example embodiments, each of the NVM devices NVM11 to NVMmn may be implemented as an arbitrary memory unit that may operate according to an individual command from the memory controller 16. For example, each of the NVM devices NVM11 to NVMmn may be implemented as a chip or a die, but example embodiments are not limited thereto.

The memory controller 16 may transmit and receive signals to and from the memory device 17 through the plurality of channels CH1 to CHm. For example, the memory controller 16 may transmit commands CMDa to CMDm, addresses ADDRa to ADDRm, and data DATAa to DATAm to the memory device 17 through the channels CH1 to CHm or receive the data DATAa to DATAm from the memory device 17.

The memory controller 16 may select one of the NVM devices NVM11 to NVMmn, which is connected to each of the channels CH1 to CHm, by using a corresponding one of the channels CH1 to CHm, and transmit and receive signals to and from the selected NVM device. For example, the memory controller 16 may select the NVM device NVM11 from the NVM devices NVM11 to NVMIn connected to the first channel CH1. The memory controller 16 may transmit the command CMDa, the address ADDRa, and the data DATAa to the selected NVM device NVM11 through the first channel CH1 or receive the data DATAa from the selected NVM device NVM11.

The memory controller 16 may transmit and receive signals to and from the memory device 17 in parallel through different channels. For example, the memory controller 16 may transmit a command CMDb to the memory device 17 through the second channel CH2 while transmitting a command CMDa to the memory device 17 through the first channel CH1. For example, the memory controller 16 may receive data DATAb from the memory device 17 through the second channel CH2 while receiving data DATAa from the memory device 17 through the first channel CH1.

The memory controller 16 may control all operations of the memory device 17. The memory controller 16 may transmit a signal to the channels CH1 to CHm and control each of the NVM devices NVM11 to NVMmn connected to the channels CH1 to CHm. For instance, the memory controller 16 may transmit the command CMDa and the address ADDRa to the first channel CH1 and control one selected from the NVM devices NVM11 to NVM1n.

Each of the NVM devices NVM11 to NVMmn may operate via the control of the memory controller 16. For example, the NVM device NVM11 may program the data DATAa based on the command CMDa, the address ADDRa, and the data DATAa provided to the first channel CH1. For example, the NVM device NVM21 may read the data DATAb based on the command CMDb and the address ADDb provided to the second channel CH2 and transmit the read data DATAb to the memory controller 16.

Although FIG. 3 illustrates an example in which the memory device 17 communicates with the memory controller 16 through m channels and includes n NVM devices corresponding to each of the channels, the number of channels and the number of NVM devices connected to one channel may be variously changed.

It will be understood that the storage device 15 may be configured to perform any methods, functionality, or the like according to any of the example embodiments, including an iterative programming operation performed to program a non-volatile memory device (memory device 17), an iterative anomaly detection program to perform an iterative model to at least determine probability values each indicating a probability associated with occurrence of at least one programming anomaly in one or more programming stages of the iterative programming operation, and in some example embodiments to determine whether at least one programming anomaly has occurred in the one or more programming stages of the iterative programming operation, for example based on determining that at least one probability value at least meets a corresponding threshold probability value. For example, the storage device 15 (e.g., the memory controller 16) may include a memory (e.g., a working memory of the memory controller 16 (not shown), which may include an SSD storage device) storing a program of instructions and a processor (e.g., a CPU of the memory controller 16 (not shown)) configured to execute the program of instructions to implement any of the methods, functionalities of one or more devices, or the like according to any of the example embodiments, including the iterative anomaly detection program 900 including at least one iterative model 910 according to any of the example embodiments.

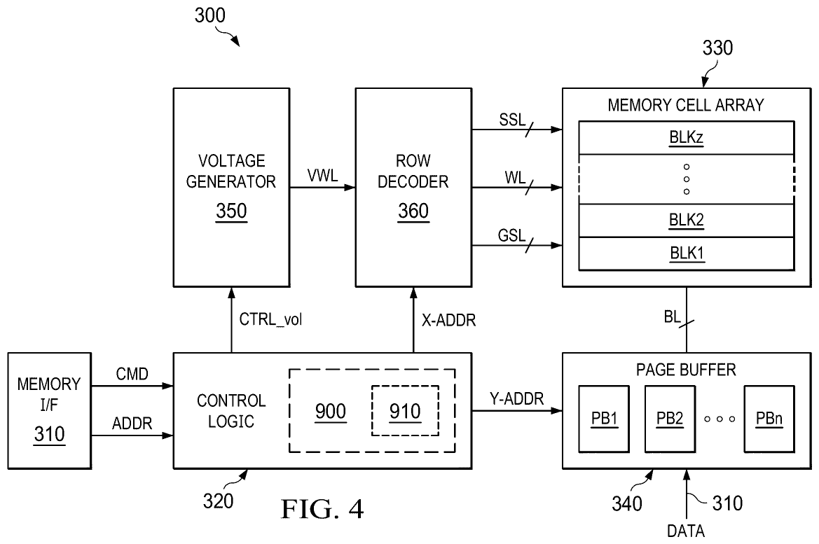

FIG. 4 is a block diagram of a memory device 300 according to some example embodiments.

Referring to FIG. 4, the memory device 300 may include a control logic circuitry 320, a memory cell array 330, a page buffer 340, a voltage generator 350, and a row decoder 360. The memory device 300 may further include a memory interface circuitry 310. In addition, the memory device 300 may further include a column logic, a pre-decoder, a temperature sensor, a command decoder, and/or an address decoder. For example, the memory device 300 may include a memory device (e.g., a non-volatile memory device, or NVM) and may include or be included in at least one of the memory device 17 as shown in FIG. 3, the NVM 220 as shown in FIG. 2, and/or at least one of the NVMs 1320a and/or 1320b as shown in FIG. 1. The memory device 300 may include a non-volatile memory device such as a NAND flash memory device, but example embodiments are not limited thereto.

The control logic circuitry 320 may control all various operations of the memory device 300. The control logic circuitry 320 may output various control signals in response to commands CMD and/or addresses ADDR from the memory interface circuitry 310. For example, the control logic circuitry 320 may output a voltage control signal CTRL_vol, a row address X-ADDR, and a column address Y-ADDR.

The control logic circuitry 320 may receive a command CMD and an address ADDR from an outside (e.g., from a memory controller via memory interface circuitry 310), and control erasure, programming and read operations of the non-volatile memory device 300 based on the command CMD and the address ADDR. An erasure operation may include performing a sequence of erase loops, and a program operation may include performing a sequence of program loops (also referred to herein interchangeably as an iterative programming operation that includes a plurality of programming stages). Each programming stage may include a program operation (e.g., a programming operation) and a verification operation. Each erase loop may include an erase operation and an erase verification operation. The read operation may include a normal read operation and data recover read operation.

The memory cell array 330 may include a plurality of memory blocks BLK1 to BLKz (here, z is a positive integer), each of which may include a plurality of memory cells. Each memory block BLK1 to BLKz may represent a plurality of memory cells connected to a same word line WL. The memory cell array 330 may be connected to the page buffer 340 through bit lines BL and be connected to the row decoder 360 through word lines WL, string selection lines SSL, and ground selection lines GSL.

In some example embodiments, the memory cell array 330 may include a 3D memory cell array, which includes a plurality of NAND strings. Each of the NAND strings may include memory cells respectively connected to word lines vertically stacked on a substrate. The disclosures of U.S. Pat. Nos. 7,679,133; 8,553,466; 8,654,587; 8,559,235; and 9,536,970 are hereby incorporated by reference. In some example embodiments, the memory cell array 330 may include a 2D memory cell array, which includes a plurality of NAND strings arranged in a row direction and a column direction.

The control logic circuitry 320 may control the voltage generator 350 to generate various operation voltages (e.g., one or more of a plurality of program voltages, a plurality of verification voltages, a plurality of read voltages, and a plurality of erase voltages) necessary for/used for the memory device 300 to operate. The control logic circuitry 320 may receive a command CMD from the external device (e.g., a memory controller and/or a host). The control logic circuitry 320 may control various components of the memory device 300 based on the received command CMD.

The page buffer 340 may include a plurality of page buffers PB1 to PBn (here, n is an integer greater than or equal to 3), which may be respectively connected to the memory cells through a plurality of bit lines BL. The page buffer 340 may select at least one of the bit lines BL in response to the column address Y-ADDR. The page buffer 340 may operate as a write driver or a sense amplifier according to an operation mode. For example, during a program operation, the page buffer 340 may apply a bit line voltage corresponding to data to be programmed, to the selected bit line. During a read operation, the page buffer 340 may sense current or a voltage of the selected bit line BL and sense data stored in the memory cell.

The voltage generator 350 may generate various kinds of voltages for program, read, and erase operations based on the voltage control signal CTRL_vol. For example, the voltage generator 350 may generate a program voltage, a read voltage, a program verification voltage, and an erase voltage as a word line voltage VWL.

The voltage generator 350 may generate a plurality of word line voltages (e.g., program voltage Vpgm which is also represented as PGM herein, verification voltage Vvfy, normal read voltage Vread) required in the programming, erasing, and verify/normal reading operations of memory cell transistors. Further, the voltage generator 350 may generate a bulk voltage Vbulk to be supplied to the bulk (substrate) in which memory cell transistors are formed. The control logic circuitry 320 may be configured to control the voltage generator 350 to generate a progression of program voltages (Vpgm) by using incremental step pulse programming (ISPP), in a programming operation.

The row decoder 360 may select one of a plurality of word lines WL and select one of a plurality of string selection lines SSL in response to the row address X-ADDR. For example, the row decoder 360 may apply the program voltage and the program verification voltage to the selected word line WL during a program operation and apply the read voltage to the selected word line WL during a read operation.

In some example embodiments, the memory device 300 according to example embodiments may store data in the memory cell array 330 through a plurality, or sequence, of program loops (also referred to herein interchangeably as programming stages). Each of the plurality of program loops (e.g., a given n-th programming stage) may include a program operation (e.g., an n-th programming stage, also referred to as a program step) in which a program voltage is applied to a selected word line, and a verification operation (also referred to herein as a verification step, a verify step, or the like) in which a verification voltage is applied to the selected word line. In one verification operation, at least one program state may be verified. In some example embodiments, the memory device 300 may perform an operation (e.g., a target dump operation) for selecting a target program state during a bit line precharge operation. In this case, a total program time of the memory device 300 may be shortened. An operation of the memory device 300 according to some example embodiments will be described with reference to accompanying drawings.

The control logic circuitry 320 controls the overall operations related to programming, erasing, and verify/normal read operations of the flash memory device 300. In the time interval during which programming is performed, the control logic circuitry 320 is configured to, for example based on controlling the voltage generator 350, cause a program voltage Vpgm to be supplied (e.g., applied) to a selected word line, a bit line voltage Vb1 to be supplied (e.g., applied) to selected bit lines, and a bulk voltage Vbulk to be supplied (e.g., applied) to a bulk (substrate) in which memory cell transistors are formed. The program voltages Vpgm, may be generated (e.g., at the voltage generator 350 based on being controlled via a command signal CTRL_VOL from the control logic circuitry 320) by using the incremental step pulse programming (ISPP) method. The level (e.g., magnitude) of the program voltage Vpgm increments in steps of a predetermined voltage increment amount (AV) each time the programming stages are repeated. A supply number, a voltage level, and a voltage supply time period of the program voltage Vpgm used in the respective programming stages may be varied according to the control of an external device (e.g., a memory controller) or of an internal device (e.g., control logic circuitry 320). Also, the control logic circuitry 320 causes a bias voltage for verification (e.g., a verification voltage) or normal reading to be supplied to selected word lines and selected bit lines during an interval when a verify read operation (e.g., verification operation) or normal read operation is conducted.

It will be understood that the memory device 300 may be configured to perform any methods, functionality, or the like according to any of the example embodiments, including an iterative programming operation performed to program a non-volatile memory device (memory device 17), an iterative anomaly detection program to perform an iterative model to at least determine probability values each indicating a probability associated with occurrence of at least one programming anomaly in one or more programming stages of the iterative programming operation, and in some example embodiments to determine whether at least one programming anomaly has occurred in the one or more programming stages of the iterative programming operation, for example based on determining that at least one probability value at least meets a corresponding threshold probability value. For example, the memory device 300 (e.g., the control logic circuitry 320) may include a memory (e.g., a working memory of the control logic circuitry 320 (not shown), which may include an SSD storage device) storing a program of instructions and a processor (e.g., a CPU of the control logic circuitry 320 (not shown)) configured to execute the program of instructions to implement any of the methods, functionalities of one or more devices, or the like according to any of the example embodiments. As shown, for example, the control logic circuitry 320 may store a program of instructions to implement an iterative anomaly detection program 900, including at least one iterative model 910 (e.g., an RNN), in a working memory (e.g., SSD storage device) included in the control logic circuitry 320, and the control logic circuitry 320 may execute the stored program of instructions to implement the iterative anomaly detection program 900, including at least one iterative model 910, according to some example embodiments.

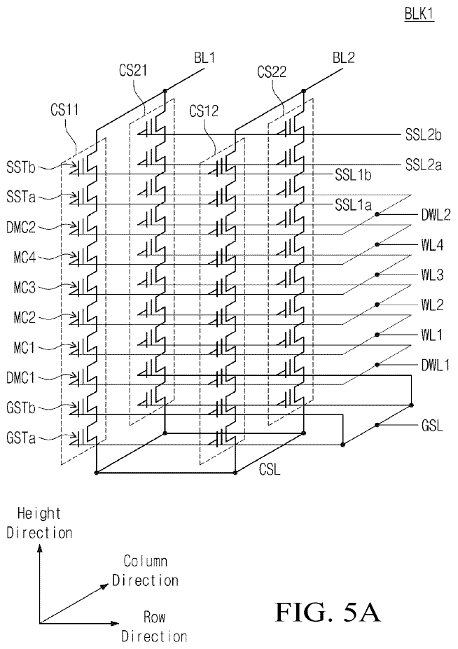

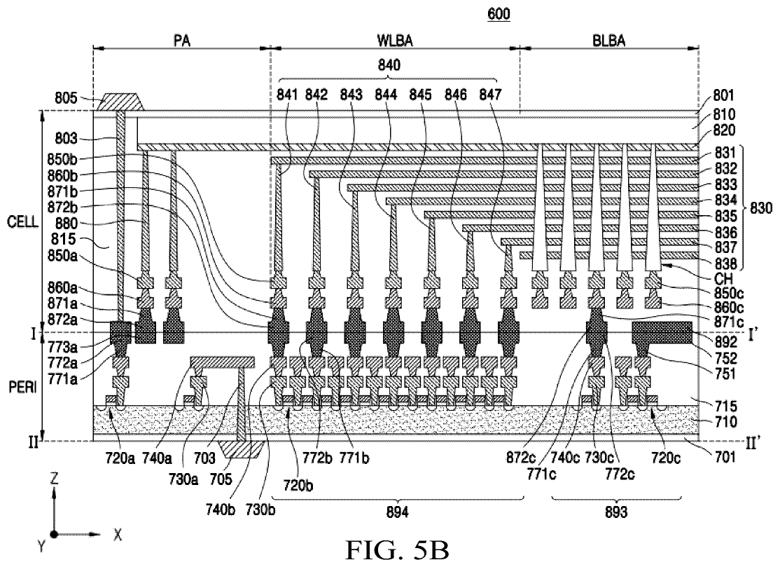

FIG. 5A is a diagram illustrating a first memory block of a plurality of memory blocks included in a memory cell array 330 in FIG. 4, according to some example embodiments.

A first memory block BLK1 will be described with reference to FIG. 4. However, it may be understood that the remaining memory blocks included in the memory cell array 330 have a structure similar to or the same as that of the first memory block BLK1, and/or may have a different structure, and example embodiments are not limited thereto.

Referring to FIGS. 4 and 5A, the first memory block BLK1 may include a plurality of cell strings CS11, CS12, CS21, and CS22. The plurality of cell strings CS11, CS12, CS21, and CS22 may be arranged in a row direction and a column direction.

Cell strings placed at the same column from among the plurality of cell strings CS11, CS12, CS21, and CS22 may be connected with the same bit line. For example, the cell strings CS11 and CS21 may be connected with a first bit line BL1, and the cell strings CS12 and CS22 may be connected with a second bit line BL2. Each of the plurality of cell strings CS11, CS12, CS21, and CS22 may include a plurality of cell transistors. Each of the plurality of cell transistors may include a charge trap flash (CTF) memory cell, but example embodiments are not limited thereto. The plurality of cell transistors may be stacked in a height direction that is a direction perpendicular to a plane (e.g., a semiconductor substrate (not illustrated)) defined by the row direction and the column direction.

The plurality of cell transistors of each cell string may be connected in series, e.g. from source of one transistor to drain of another transistor, between the corresponding bit line (e.g., BL1 or BL2) and a common source line CSL. For example, the plurality of cell transistors may include string selection transistors SSTa and SSTb, dummy memory cells DMC1 and DMC2 that are not electrically active but may provide structural support, memory cells MC1 to MC4, and ground selection transistors GSTa and GSTb. The string selection transistors SSTa and SSTb that are connected in series may be provided or connected between the serially-connected memory cells MC1 to MC4 and the corresponding bit line (e.g., BL1 and BL2). The ground selection transistors GSTa and GSTb that are connected in series may be provided or connected between the serially-connected memory cells MC1 to MC4 and the common source line CSL. In some example embodiments, the second dummy memory cell DMC2 may be provided between the serially-connected string selection transistors SSTa and SSTb and the serially-connected memory cells MC1 to MC4, and the first dummy memory cell DMC1 may be provided between the serially-connected memory cells MC1 to MC4 and the serially-connected ground selection transistors GSTa and GSTb.

Memory cells placed at the same height from among the memory cells MC1 to MC4 of the plurality of cell strings CS11, CS12, CS21, and CS22 may share the same word line. For example, the first memory cells MC1 of the plurality of cell strings CS11, CS12, CS21, and CS22 may be placed at the same height from the semiconductor substrate (not illustrated) and may share a first word line WL1. The second memory cells MC2 of the plurality of cell strings CS11, CS12, CS21, and CS22 may be placed at the same height from the semiconductor substrate (not illustrated) and may share a second word line WL2. Likewise, the third memory cells MC3 of the plurality of cell strings CS11, CS12, CS21, and CS22 may be placed at the same height from the semiconductor substrate (not illustrated) and may share a third word line WL3, and the fourth memory cells MC4 of the plurality of cell strings CS11, CS12, CS21, and CS22 may be placed at the same height from the semiconductor substrate (not illustrated) and may share a fourth word line WL4.

Dummy memory cells placed at the same height from among the dummy memory cells DMC1 and DMC2 of the plurality of cell strings CS11, CS12, CS21, and CS22 may share the same dummy word line. For example, the first dummy memory cells DMC1 of the plurality of cell strings CS11, CS12, CS21, and CS22 may share a first dummy word line DWL1, and the second dummy memory cells DMC2 of the plurality of cell strings CS11, CS12, CS21, and CS22 may share a second dummy word line DWL2.

String selection transistors placed at the same height and the same row from among the string selection transistors SSTa and SSTb of the plurality of cell strings CS11, CS12, CS21, and CS22 may share the same string selection line. For example, the string selection transistors SSTb of the cell strings CS11 and CS12 may share a string selection line SSL1b, and the string selection transistors SSTa of the cell strings CS11 and CS12 may share a string selection line SSLla. The string selection transistors SSTb of the cell strings CS21 and CS22 may be connected with a string selection line SSL2b, and the string selection transistors SSTa of the cell strings CS21 and CS22 may be connected with a string selection line SSL2a.

Although not illustrated in FIG. 5A, string selection transistors placed at the same row from among the string selection transistors SSTa and SSTb of the plurality of cell strings CS11, CS12, CS21, and CS22 may share the same string selection line. For example, the string selection transistors SSTb and SSTa of the cell strings CS11 and CS12 may share a first string selection line, and the string selection transistors SSTb and SSTa of the cell strings CS21 and CS22 may share a second string selection line different from the first string selection line.

Ground selection transistors placed at the same height and the same row from among the ground selection transistors GSTa and GSTb of the plurality of cell strings CS11, CS12, CS21, and CS22 may be connected with the same ground selection line. For example, the ground selection transistors GSTb of the cell strings CS11 and CS12 may be connected with a first ground selection line, and the ground selection transistors GSTa of the cell strings CS11 and CS12 may share a second ground selection line. The ground selection transistors GSTb of the cell strings CS21 and CS22 may be connected with a third ground selection line, and the ground selection transistors GSTa of the cell strings CS21 and CS22 may be connected with a fourth ground selection line.

As illustrated in FIG. 5A, the ground selection transistors GSTb and GSTa of the plurality of cell strings CS11, CS12, CS21, and CS22 may share the same ground selection line GSL. Alternatively or additionally, at least some ground selection transistors placed at the same height from among the ground selection transistors GSTb and GSTa of the plurality of cell strings CS11, CS12, CS21, and CS22 may share the same ground selection line. Alternatively or additionally, ground selection transistors placed at the same row from among the ground selection transistors GSTb and GSTa of the plurality of cell strings CS11, CS12, CS21, and CS22 may share the same ground selection line.

Although not illustrated in FIG. 5A, each of the plurality of cell strings CS11, CS12, CS21, and CS22 of the first memory block BLK1 may further include an erase control transistor. The erase control transistors of the plurality of cell strings CS11, CS12, CS21, and CS22 may be placed at the same height from the semiconductor substrate and may be connected with the same erase control line. For example, in each of the plurality of cell strings CS11, CS12, CS21, and CS22, the erase control transistor may be interposed between the ground selection transistor GSTa and the common source line CSL. Alternatively, the erase control transistor may be interposed between the corresponding bit line BL1 or BL2 and the string selection transistor SSTb. However, example embodiments are not limited thereto.

In some example embodiments, the first memory block BLK1 illustrated in FIG. 5 is only an example. The number of cell strings may increase or decrease, and the number of rows of cell strings and the number of columns of cell strings may increase or decrease depending on the number of cell strings. Additionally or alternatively, in the first memory block BLK1, the number of cell transistors (e.g., GST, MC, DMC, and SST) may increase or decrease, and the height of the first memory block BLK1 may increase or decrease depending on the number of cell transistors. Additionally or alternatively, the number of lines (e.g., GSL, WL, DWL, and SSL) connected with cell transistors may increase or decrease depending on the number of cell transistors. In some example embodiments, as the number of cell transistors of the first memory block BLK1 increases, the first memory block BLK1 may have a multi-stack structure.

FIG. 5B is a diagram illustrating a memory device 600 according to some example embodiments. The memory device 600 may be included in at least a portion of the memory device 300 of FIG. 3, the memory device 17 of FIG. 3, the NVM 220 of FIG. 2, the NVMS 1320a and/or 1320b, or any combination thereof.

Referring to FIG. 5B, a memory device 600 may have a chip-to-chip (C2C) structure. The C2C structure may refer to a structure formed by manufacturing an upper chip including a cell region CELL on a first wafer, manufacturing a lower chip including a peripheral circuit region PERI on a second wafer, separate from the first wafer, and then bonding the upper chip and the lower chip to each other. Here, the bonding process may include a method of electrically connecting a bonding metal formed on an uppermost metal layer of the upper chip and a bonding metal formed on an uppermost metal layer of the lower chip. For example, when the bonding metals may include copper (Cu) using a Cu-to-Cu bonding. The example embodiments, however, may not be limited thereto. For example, the bonding metals may also be formed of aluminum (Al) or tungsten (W).

Each of the peripheral circuit region PERI and the cell region CELL of the memory device 600 may include an external pad bonding area PA, a word line bonding area WLBA, and a bit line bonding area BLBA.

The peripheral circuit region PERI may include a first substrate 710, an interlayer insulating layer 715, a plurality of circuit elements 720a, 720b, and 720c formed on the first substrate 710, first metal layers 730a, 730b, and 730c respectively connected to the plurality of circuit elements 720a, 720b, and 720c, and second metal layers 740a, 740b, and 740c formed on the first metal layers 730a, 730b, and 730c. In some example embodiments, the first metal layers 730a, 730b, and 730c may be formed of tungsten having relatively high electrical resistivity, and the second metal layers 740a, 740b, and 740c may be formed of copper having relatively low electrical resistivity.

In some example embodiments illustrated in FIG. 5B, although only the first metal layers 730a, 730b, and 730c and the second metal layers 740a, 740b, and 740c are shown and described, the example embodiments are not limited thereto, and one or more additional metal layers may be further formed on the second metal layers 740a, 740b, and 740c. At least a portion of the one or more additional metal layers formed on the second metal layers 740a, 740b, and 740c may be formed of aluminum or the like having a lower electrical resistivity than those of copper forming the second metal layers 740a, 740b, and 740c.

The interlayer insulating layer 715 may be disposed on the first substrate 710 and cover the plurality of circuit elements 720a, 720b, and 720c, the first metal layers 730a, 730b, and 730c, and the second metal layers 740a, 740b, and 740c. The interlayer insulating layer 715 may include an insulating material such as silicon oxide, silicon nitride, or the like.

Lower bonding metals 771b and 772b may be formed on the second metal layer 740b in the word line bonding area WLBA. In the word line bonding area WLBA, the lower bonding metals 771b and 772b in the peripheral circuit region PERI may be electrically bonded to upper bonding metals 871b and 872b of the cell region CELL. The lower bonding metals 771b and 772b and the upper bonding metals 871b and 872b may be formed of aluminum, copper, tungsten, or the like. Further, the upper bonding metals 871b and 872b in the cell region CELL may be referred to as first metal pads and the lower bonding metals 771b and 772b in the peripheral circuit region PERI may be referred to as second metal pads.

The cell region CELL may include at least one memory block. The cell region CELL may include a second substrate 810 and a common source line 820. On the second substrate 810, a plurality of word lines 831 to 838 (i.e., 830) may be stacked in a direction (a Z-axis direction), perpendicular to an upper surface of the second substrate 810. At least one string select line and at least one ground select line may be arranged on and below the plurality of word lines 830, respectively, and the plurality of word lines 830 may be disposed between the at least one string select line and the at least one ground select line.

In the bit line bonding area BLBA, a channel structure CH may extend in a direction (a Z-axis direction), perpendicular to the upper surface of the second substrate 810, and pass through the plurality of word lines 830, the at least one string select line, and the at least one ground select line. The channel structure CH may include a data storage layer, a channel layer, a buried insulating layer, and the like, and the channel layer may be electrically connected to a first metal layer 850c and a second metal layer 860c. For example, the first metal layer 850c may be a bit line contact, and the second metal layer 860c may be a bit line. In some example embodiments, the bit line 860c may extend in a first direction (a Y-axis direction), parallel to the upper surface of the second substrate 810.

In some example embodiments illustrated in FIG. 5B, an area in which the channel structure CH, the bit line 860c, and the like are disposed may be defined as the bit line bonding area BLBA. In the bit line bonding area BLBA, the bit line 860c may be electrically connected to the circuit elements 720c providing a page buffer 893 in the peripheral circuit region PERI. The bit line 860c may be connected to upper bonding metals 871c and 872c in the cell region CELL, and the upper bonding metals 871c and 872c may be connected to lower bonding metals 771c and 772c connected to the circuit elements 720c of the page buffer 893. In some example embodiments, a program operation may be executed based on a page unit as write data of the page-unit is stored in the page buffer 893, and a read operation may be executed based on a sub-page unit as read data of the sub-page unit is stored in the page buffer 893. Also, in the program operation and the read operation, units of data transmitted through bit lines may be different from each other.

In the word line bonding area WLBA, the plurality of word lines 830 may extend in a second direction (an X-axis direction), parallel to the upper surface of the second substrate 810 and perpendicular to the first direction, and may be connected to a plurality of cell contact plugs 841 to 847 (i.e., 840). The plurality of word lines 830 and the plurality of cell contact plugs 840 may be connected to each other in pads provided by at least a portion of the plurality of word lines 830 extending in different lengths in the second direction. A first metal layer 850b and a second metal layer 860b may be connected to an upper portion of the plurality of cell contact plugs 840 connected to the plurality of word lines 830, sequentially. The plurality of cell contact plugs 840 may be connected to the peripheral circuit region PERI by the upper bonding metals 871b and 872b of the cell region CELL and the lower bonding metals 771b and 772b of the peripheral circuit region PERI in the word line bonding area WLBA.

The plurality of cell contact plugs 840 may be electrically connected to the circuit elements 720b forming a row decoder 894 in the peripheral circuit region PERI. In some example embodiments, operating voltages of the circuit elements 720b of the row decoder 894 may be different than operating voltages of the circuit elements 720c forming the page buffer 893. For example, operating voltages of the circuit elements 720c forming the page buffer 893 may be greater than operating voltages of the circuit elements 720b forming the row decoder 894.

A common source line contact plug 880 may be disposed in the external pad bonding area PA. The common source line contact plug 880 may be formed of a conductive material such as a metal, a metal compound, polysilicon, or the like, and may be electrically connected to the common source line 820. A first metal layer 850a and a second metal layer 860a may be stacked on an upper portion of the common source line contact plug 880, sequentially. For example, an area in which the common source line contact plug 880, the first metal layer 850a, and the second metal layer 860a are disposed may be defined as the external pad bonding area PA.

Input-output pads 705 and 805 may be disposed in the external pad bonding area PA. Referring to FIG. 5B, a lower insulating film 701 covering a lower surface of the first substrate 710 may be formed below the first substrate 710, and a first input-output pad 705 may be formed on the lower insulating film 701. The first input-output pad 705 may be connected to at least one of the plurality of circuit elements 720a, 720b, and 720c disposed in the peripheral circuit region PERI through a first input-output contact plug 703, and may be separated from the first substrate 710 by the lower insulating film 701. In addition, a side insulating film may be disposed between the first input-output contact plug 703 and the first substrate 710 to electrically separate the first input-output contact plug 703 and the first substrate 710.

Referring to FIG. 5B, an upper insulating film 801 covering the upper surface of the second substrate 810 may be formed on the second substrate 810, and a second input-output pad 805 may be disposed on the upper insulating film 801. The second input-output pad 805 may be connected to at least one of the plurality of circuit elements 720a, 720b, and 720c disposed in the peripheral circuit region PERI through a second input-output contact plug 803. In some example embodiments, the second input-output pad 805 is electrically connected to a circuit element 720a.

According to some example embodiments, the second substrate 810 and the common source line 820 may not be disposed in an area in which the second input-output contact plug 803 is disposed. Also, the second input-output pad 805 may not overlap the word lines 830 in the third direction (the Z-axis direction). Referring to FIG. 5B, the second input-output contact plug 803 may be separated from the second substrate 810 in a direction, parallel to the upper surface of the second substrate 810, and may pass through the interlayer insulating layer 815 of the cell region CELL to be connected to the second input-output pad 805.

According to some example embodiments, the first input-output pad 705 and the second input-output pad 805 may be selectively formed. For example, the memory device 600 may include only the first input-output pad 705 disposed on the first substrate 710 or the second input-output pad 805 disposed on the second substrate 810. Alternatively, the memory device 600 may include both the first input-output pad 705 and the second input-output pad 805.

A metal pattern provided on an uppermost metal layer may be provided as a dummy pattern or the uppermost metal layer may be absent, in each of the external pad bonding area PA and the bit line bonding area BLBA, respectively included in the cell region CELL and the peripheral circuit region PERI.

In the external pad bonding area PA, the memory device 600 may include a lower metal pattern 773a, corresponding to an upper metal pattern 872a formed in an uppermost metal layer of the cell region CELL, and having the same cross-sectional shape as the upper metal pattern 872a of the cell region CELL so as to be connected to each other, in an uppermost metal layer of the peripheral circuit region PERI. In the peripheral circuit region PERI, the lower metal pattern 773a formed in the uppermost metal layer of the peripheral circuit region PERI may not be connected to a contact. Similarly, in the external pad bonding area PA, an upper metal pattern 872a, corresponding to the lower metal pattern 773a formed in an uppermost metal layer of the peripheral circuit region PERI, and having the same shape as a lower metal pattern 773a of the peripheral circuit region PERI, may be formed in an uppermost metal layer of the cell region CELL.

The lower bonding metals 771b and 772b may be formed on the second metal layer 740b in the word line bonding area WLBA. In the word line bonding area WLBA, the lower bonding metals 771b and 772b of the peripheral circuit region PERI may be electrically connected to the upper bonding metals 871b and 872b of the cell region CELL by a Cu-to-Cu bonding.

Further, in the bit line bonding area BLBA, an upper metal pattern 892, corresponding to a lower metal pattern 752 formed in the uppermost metal layer of the peripheral circuit region PERI, and having the same cross-sectional shape as the lower metal pattern 752 of the peripheral circuit region PERI, may be formed in an uppermost metal layer of the cell region CELL. A contact may not be formed on the upper metal pattern 892 formed in the uppermost metal layer of the cell region CELL.

In some example embodiments, corresponding to a metal pattern formed in an uppermost metal layer in one of the cell region CELL and the peripheral circuit region PERI, a reinforcement metal pattern having the same cross-sectional shape as the metal pattern may be formed in an uppermost metal layer in the other one of the cell region CELL and the peripheral circuit region PERI. A contact may not be formed on the reinforcement metal pattern.

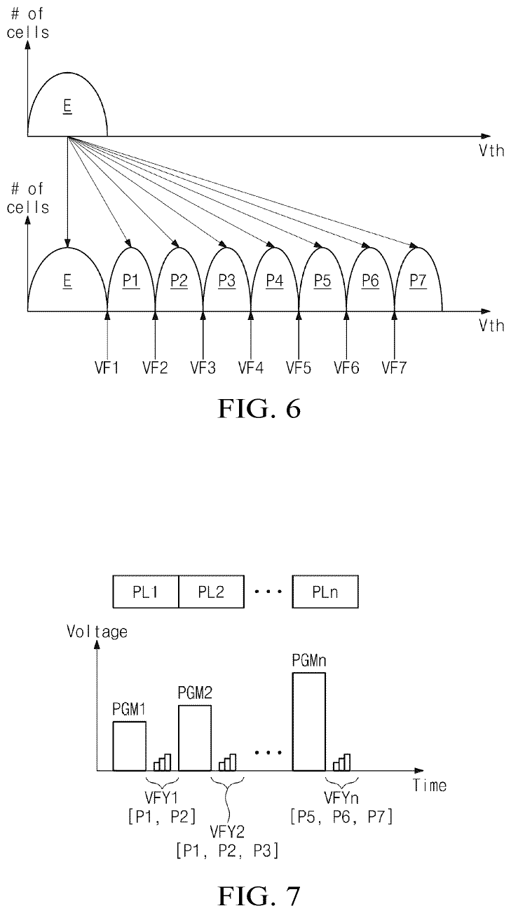

FIG. 6 is a distribution diagram for describing an iterative programming operation to program a non-volatile memory device, according to some example embodiments. FIG. 7 is a timing diagram for describing an iterative programming operation to program a non-volatile memory device, according to some example embodiments. In FIGS. 6 and 7, the non-volatile memory device may be any of the non-volatile memory devices according to any of the example embodiments, including any of NVMs 1320a and/or 1320b in FIG. 1, NVM 220 in FIG. 2, memory device 17 in FIG. 3, memory device 300 in FIG. 4, any combination thereof, or the like.

In some example embodiments, in the distribution diagrams of FIG. 6, a horizontal axis represents a threshold voltage of a memory cell of the memory device, and a vertical axis represents the number of memory cells, e.g. the number of memory cells within a block (e.g., any of memory blocks BLK1 to BLKz in FIG. 4 that are connected to a particular, selected word line of the non-volatile memory device) and/or within a semiconductor device have the corresponding threshold voltage. In some example embodiments, in the timing diagram of FIG. 7, a horizontal axis represents a time, and a vertical axis represents a word line voltage applied to a selected word line. For convenience of description, it is assumed that each memory cell is a triple level cell storing 3-bit data, e.g. three bits such as “010” may be stored within a memory cell. However, example embodiments are not limited thereto. For example, each memory cell may be a single level cell (SLC) storing one bit, or a multi-level cell (MLC) storing, e.g., two cells, or a quad level cell (QLC) storing two or more bits. As described below in more detail, a number of latches LAT_1 to LAT_3 may be determined based on the number of bits that each memory cell may store; however, example embodiments may not be limited thereto.

A mapping between threshold voltages and logical bits may be predefined and/or dynamically defined. Additionally or alternatively, memory cells such as memory cells MC1 to MC4 (e.g., as shown in FIG. 5A) having a threshold voltage less than zero volts may be in an erased state, and memory cells such as memory cells MC1 to MC4 having a threshold voltage greater than zero volts may be in a programmed state; however, example embodiments are not limited thereto. For example, the seventh program state P7 may correspond to a bit value of “000” or “111”; example embodiments are not limited thereto.

Referring to FIGS. 4 and 6, the memory device 300 may store and/or program data in memory cells by changing threshold voltages of a plurality of memory cells (e.g., MC1 to MC4 of FIG. 5A) included in the memory cell array 330.

For example, the memory device 300 may perform a program operation (e.g., an iterative programming operation as described herein) on the memory cells based on data to be stored, such as memory cells of an erase state “E” has one of the erase state “E” and a plurality of program states P1 to P7. In some example embodiments, the iterative programming operation may be performed in units of word lines and/or in units of pages.

In some example embodiments, after a programming operation (e.g., iterative programming operation) has been performed in a non-volatile memory device, it may be determined whether a memory cell transistor is correctly programmed to have a required threshold voltage Vth correctly indicating the stored data value. Such operation is called a verification operation (or, a verify-read operation, a verifying operation, or the like). In general, a programming operation and a verification operation form one loop, also referred to herein interchangeably as an iteration, a cycle, a stage, or the like, of the programming operation, and such loops are repeated a particular number of times. Accordingly, the performing of a particular number of program loops may be interchangeably referred to as performing a particular number of programming stages (e.g., iteratively performed programming stages) of an iterative programming operation. For example, after a memory cell transistor is programmed, whether a threshold voltage Vth of a programmed memory cell transistor is higher than a particular verification voltage (also referred to as a verify-read voltage, also referred to herein as a verification voltage V′) is determined based on a verification voltage (e.g., a verify read voltage) that is applied to a selected word line. If a threshold voltage Vth of a programmed memory cell transistor is determined to be higher than a verify-read voltage (e.g., V′), a re-programming operation of a memory cell transistor is not performed, and the next loop is cancelled. Then such a memory cell transistor may be deemed a correctly programmed cell. On the other hand, if a threshold voltage Vth of a programmed memory cell transistor is determined to be lower than a verify-read voltage, a re-programming operation of a memory cell transistor is performed in the next loop. The number of programmed cells may gradually increase with repetitions of the program loops. In other words, the number of memory cell transistors to-be-programmed (or, number of bits to-be-programmed) may gradually decrease with repetitions of the program loops.

In some example embodiments, the memory device 300 may perform the iterative programming operation based on an incremental step pulse programming (ISPP) scheme. For example, as illustrated in FIG. 7, the memory device 300 may perform the iterative programming operation through a sequence of a plurality of 1 to n-th programming stages (also referred to herein interchangeably as program loops) PL1 to PLn. Each of the 1 to n-th programming stages PL1 to PLn may include a program step (also referred to herein interchangeably as a program operation) of applying a program voltage to a selected word line and/followed by a verify step (also referred to herein interchangeably as a verification operation) of verifying program states of memory cells.

For example, the memory device 300 may perform the first programming stage PL1. The first programming stage PL1 may include a first program step and a first verify step VFY1. In the first program step, a first program voltage PGM1 may be applied to a selected word line to change threshold voltages of memory cells connected to the selected word line. In the first verify step VFY1, one or more of a plurality of verification voltages VF1 to VF7 may be sequentially applied to the selected word line to verify program states of the memory cells connected to the selected word line.

Afterwards (e.g., subsequent to completing the first verify step VFY1), the memory device 300 may perform the second programming stage PL2. The second programming stage PL2 may include a second program step and/followed by a second verify step VFY2. In the second program step, a second program voltage PGM2 may be applied to the selected word line to change threshold voltages of the memory cells connected to the selected word line. In the second verify step VFY2, one or more of the plurality of verification voltages VF1 to VF7 may be sequentially applied to the selected word line to verify program states of the memory cells connected to the selected word line.

Afterwards (e.g., subsequent to completing the second verify step VFY2), the memory device 300 may perform the n-th programming stage PLn. The n-th programming stage PLn may include an n-th program step and/followed by an n-th verify step VFYn. In the n-th program step, an n-th program voltage PGMn may be applied to the selected word line to change threshold voltages of the memory cells connected to the selected word line. In the n-th verify step VFYn, one or more of the plurality of verification voltages VF1 to VF7 may be sequentially applied to the selected word line to verify program states of the memory cells connected to the selected word line.

In some example embodiments, as a programming stage is repeatedly (e.g., iteratively) performed, a magnitude of a program voltage that is applied to a selected word line may stay the same or may increase. For example, the second program voltage PGM2 may be greater in magnitude than the first program voltage PGM1 as much as the given level. The n-th program voltage PGMn may be greater in magnitude than a program voltage of an (n−1)-th programming stage as the given level. In each programming stage, a program voltage may be set to a given level (e.g., a given magnitude) or may be variable depending on states of memory cells.

In some example embodiments, memory cells may be selectively verified in a verify step depending on a programming stage. For example, in the first verify step VFY1 of the first programming stage PL1, memory cells corresponding to the first and second program states P1 and P2 may be verified. In this case, the first verify step VFY1 may be performed by selectively precharging bit lines connected with the memory cells corresponding to the first and second program states P1 and P2 and sequentially applying the first and second verification voltages VF1 and VF2 to the selected word line. In more detail, to verify memory cells corresponding to the first program state P1, the memory device 300 may selectively precharge a bit line connected with a memory cell corresponding to the first program state P1 and may apply the first verification voltage VF1 for verifying the first program state P1 to the selected word line. Afterwards, to verify memory cells corresponding to the second program state P2, the memory device 300 may selectively precharge a bit line connected with a memory cell corresponding to the second program state P2 and may apply the second verification voltage VF2 for verifying the second program state P2 to the selected word line.

Below, to describe some example embodiments of inventive concepts more easily, the term “first to seventh verification operations” are used. The first program verification operation may indicate an operation of verifying memory cells, which correspond to the first program state P1 or are to be programmed to the first program state P1, from among memory cells connected with a selected word line. Likewise, the second to seventh verification operations may indicate operations of verifying memory cells, which correspond to the second to seventh program states P2 to P7 or are to be programmed to the second to seventh program states P2 to P7, from among the memory cells connected with the selected word line. For example, one verify step included in one programming stage may include one or more of the first to seventh verification operations.

Accordingly, it will be understood that a given n-th programming stage may include performing a set of L verification operations that are each associated with a particular verification voltage on a plurality of memory cells connected to a selected word line, where “L” may be any positive integer and may be the same as or different from (e.g., may be independent of) the value of “n”. In some example embodiments, a same quantity “L” of verification operations are performed in each separate programming stage of the sequence of 1 to n-th (herein interchangeably first to n-th) programming stages.

In some example embodiments, an execution order of verification operations included in one verify step from among the first to seventh verification operations may be variously changed. For example, in one verify step, when the fifth to seventh verification operations are performed, the fifth to seventh verification operations may be performed in the order of the fifth verification operations, the sixth verification operations, and the seventh verification operations, in the order of the verification operations, the sixth verification operations, and the fifth verification operations, or in an arbitrary order. The terms described above are to describe some example embodiments easily, and it may be understood that the scope and spirit of the example embodiments are not limited by the terms.

In the second verify step VFY2 of the second programming stage PL2, the first to third verification operations may be performed. For example, in the second verify step VFY2, the first to third verification operations may be sequentially performed on memory cells having the first to third program states P1, P2, and P3 from among the memory cells connected with the selected word line. Likewise, in the n-th verify step VFYn of the n-th programming stage PLn, the fifth to seventh verification operations may be performed. For example, in the n-th verify step VFYn, the fifth to seventh program state verifications may be sequentially performed on memory cells having the fifth to seventh program states P5, P6, and P7 from among the memory cells connected with the selected word line.

As described above, in the verify steps VFY1 to VFYn of the plurality of programming stages PL1 to PLn, a verification operation may be performed on some of memory cells connected with a selected word line, depending on a relevant program state. In this case, only bit lines corresponding to some memory cells may be selectively precharged to perform the verification operation on some memory cells.

For example, the memory device 300 may perform the fifth to seventh verification operations in the n-th verify step VFYn. In this case, in the seventh verification operation, the memory device 300 may selectively precharge bit lines connected with memory cells corresponding to the seventh program state P7, through a dump operation of latches included in the page buffer circuit 340. After the seventh verification operation is completed, the memory device 300 may perform the sixth verification operation.

In some example embodiments, the memory device 300 according to some example embodiments may perform a dump operation for selectively precharging bit lines connected with memory cells corresponding to the sixth program state P6 during a bit line precharge operation in the seventh verification operation. In other words, during a bit line precharge period of a current verification operation, a dump operation for selecting a bit line to be precharged in a next verification operation may be performed. In this case, a total program time may be shortened.

In some example embodiments, the above program scheme is only an example, and example embodiments are not limited thereto. For example, the memory device 300 may perform a word line or page-based program operation in various schemes such as a shadow program scheme, a fast program scheme, and a reprogram scheme.

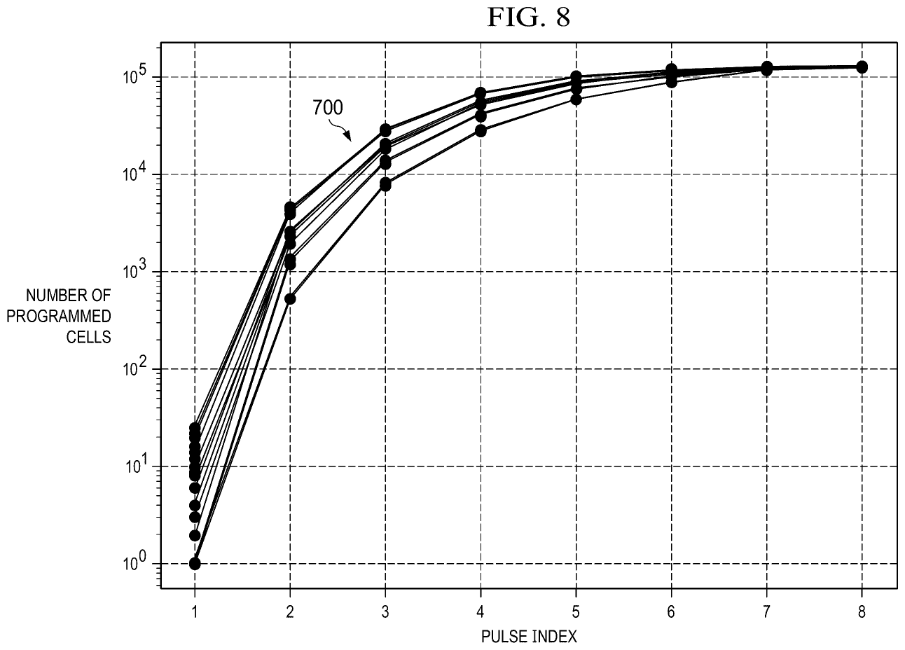

FIG. 8 illustrates measured programming rates of a plurality of iterative programming operations performed on a nonvolatile memory device, according to some example embodiments.

In some example embodiments, still referring to a memory device such as memory device 300 in FIG. 4, one or more errors (also referred to as one or more programming anomalies, one or more programming errors, or the like) may occur during an iterative programming operation performed on at least a selected word line of a nonvolatile memory device. Such programming anomalies may typically be detected based on detecting that a low number of memory cells connected to a selected word line have reached a desired verify level (e.g., a number of memory cells having a threshold voltage that is equal to or greater than a particular verification voltage) after completion of the final programming stage of the iterative programming operation is less than a particular threshold value (said particular threshold value may be stored at a memory of a device). In response to detection of such a programming anomaly, the iterative programming operation may be determined to have failed, and in response to such a determination, a recovery action may be performed, which may including a corrective action including a mark-up of the selected word line and memory cells connected thereto (e.g., block) at which the iterative programming operation is being performed as a bad block (e.g., BLK1 in FIG. 4), allocating a new address for the iterative programming operation (e.g., BLK2 in FIG. 4) and repeating the iterative programming operation at the new allocated address (e.g., BLK2 in FIG. 4), and/or various error correction operations.

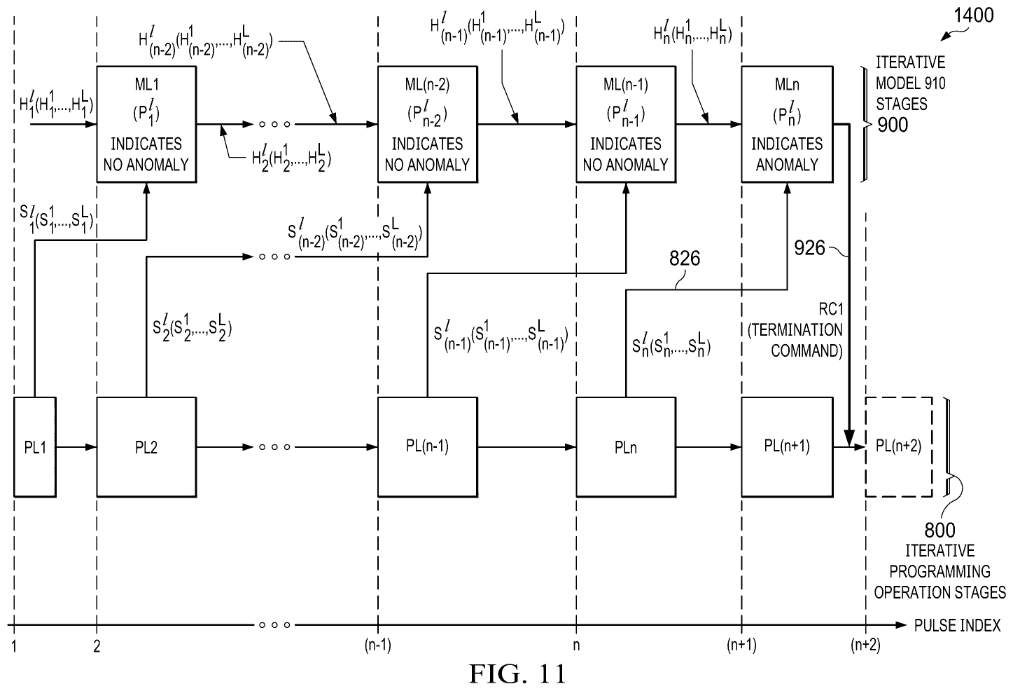

In some example embodiments, and as shown in at least FIG. 11, an iterative anomaly detection program 900 is performed to determine whether at least one programming anomaly has occurred in at least 1 to n-th programming stages (e.g., first to n-th programming stages) of an iterative programming operation 800 of N programming stages, where N is a positive integer and “n” is a positive integer inclusively between 1 and N. The iterative anomaly detection program 900 may be at least partially performed during the iterative programming operation 800 (e.g., prior to completion of the final programming stage N of the iterative programming operation). For example, the iterative anomaly detection program 900 may include applying results of a verify step (e.g., verification operation) of a given (n-th) programming stage of an iterative programming operation 800 to a corresponding (n-th) model stage of an iterative model 910 that uses the results of the given (n-th) programming stage to generate an output that may be used to determine whether at least one programming anomaly has occurred in the iterative programming operation up to at least the given (n-th) programming stage (e.g., at least one programming anomaly in the 1 to n-th programming stages). In some example embodiments, the model stages of the iterative model 910, also referred to as model iterations, model loops, model repetitions, model cells, or the like, are each performed in response to a separate programing stage of the iterative programming operation 800 being performed, such that a separate model stage of the iterative anomaly detection program 900 may be performed in response to each programming stage.

Accordingly, the iterative anomaly detection program 900 may enable detection of a programming anomaly in an iterative programming operation prior to completion of a predetermined “N” programming stages of the iterative programming operation 800, and thus a recovery action (e.g., terminating the programming operation, generating a warning, performing a correction operation, etc.) may be initiated prior to the time step at which the final “N” programming stage of the programming operation would be performed if anomaly detection were not performed until after the final programming stage were completed. For example, an iterative programming operation 800 in which a programming anomaly is determined to occur (also referred to herein as a faulty programming operation) may be terminated “early” based on the iterative anomaly detection program 900 determining the occurrence of at least one programming anomaly in the iterative programming operation, thereby enabling recovery from the programming anomaly to also be initiated and completed “early.” As a result, a device performing the iterative programming operation 800 together with the iterative anomaly detection program 900 (e.g., performing method 1400 as shown in at least FIG. 11) may detect programming anomalies more quickly, thereby enabling faster response to programming anomalies and thus enabling faster performance of corrective action to recover from the determined programming anomalies. Thus, performance of a memory device may be improved based on the memory device being configured to recover more quickly from programming anomalies during an iterative programming operation.

In some example embodiments, the iterative anomaly detection program 900 determines whether at least one programming anomaly has occurred in the 1 to n-th programming stages based on determining a probability, also referred to herein as a “probability value” that is associated with occurrence of at least one programming anomaly in the 1 to n-th programming stages of the iterative programming operation. The probability value may indicate a likelihood that a programming rate of the iterative programming operation 800 (e.g., the rate at which memory cells are programmed to a desired verify level over the source of at least “n” programming stages of the iterative programming operation) indicates that the 1 to n-th programming stages of the iterative programming operation 800 are free of anomalies. Alternatively or additionally, the probability value may indicate a likelihood that a programming rate of the iterative programming operation indicates that at least one programming anomaly has occurred during the 1 to n-th programming stages. The probability value may be determined based on implementing the iterative model 910 to process data that is generated based on performing the 1 to n-th programming stages to determine how “unusual” the programming rate of the iterative programming operation 800 is at least at the n-th programming stage in comparison to a non-faulty, or “standard” programming rate. For example, the probability value may indicate a statistical variance of an iterative programming operation 800 in a probability distribution (e.g., conditional probability distribution) where the variance indicates whether the iterative programming operation 800 is sufficiently “unusual” to indicate occurrence or absence of a programming anomaly in the iterative programming operation 800. The probability value may be compared with a threshold probability value to determine occurrence of at least one anomaly based on whether the probability value at least meets the threshold probability value.

For example, FIG. 8 illustrates a plurality of typical (e.g., non-faulty, non-anomalous, anomaly-free, “standard,” etc.) programming rates 700 as a plurality of progressions, or sequences of the number of cells having a threshold voltage that is equal to or greater than a particular verification voltage Vvfy (e.g., a verify level) at each of pulse indexes 1 to 8 in each of a plurality of iterative programming operations. As shown in FIG. 8, in standard (non-anomalous) iterative programming operations, the number of cells having a threshold voltage Vth that is equal to or greater than a particular verification voltage V′ such that the cells are “programmed” at a given programming stage “n” is expressed herein as

$${S}_{n}^{l} .$$

Tne standard programming rates 700 in FIG. 8 are each illustrated as a separate dash-line sequence of verification result values

$$( {S}_{1}^{l} , {S}_{2}^{l} , … , {S}_{n}^{l} )$$

measured on a non-volatile memory device at each of programming stages 1 to 8 during an iterative programming operation that includes at least 8 programming stages and is performed to program a particular non-volatile memory device having a particular number of memory cells (e.g., more than 105). The non-volatile memory device from which the typical programming rates 700 are measured may be a triple level cell (TLC) flash device having a particular number of memory cells (e.g., more than 105).

As shown, the programming rates 700 of the standard iterative programming operations performed to program a particular non-volatile memory device exhibit a relatively similar shape and progression of programmed cells through the programming stages 1 to 8, where the programming rates 700 of the standard iterative programming operations are shown to rapidly increase through the 8 programming stages of the iterative programming operations represented in FIG. 8 at a similar rate. In some example embodiments, it will be understood that a “faulty” iterative programming operation having at least one programming anomaly may have a programming rate that is detectably different from that of programming rates of standard (e.g., non-faulty) iterative programming operations. The iterative anomaly detection program 900 may perform an iterative model 910 to generate outputs that enable detection of at least one programming anomaly in an iterative programming operation 800 based on determining a probability value indicating a likelihood that the iterative programming operation includes or does not include at least one programming anomaly. Restated, the probability value may indicate how “unusual” the programming rate of the instant iterative programming operation up to a given n-th programming stage is, in view of programming rates of “standard” non-faulty iterative programming operations up to the given programming stage, where “unusual” may refer to an excessive (e.g., beyond a threshold value) deviation or variance from a standard programming rate that is beyond a threshold deviation indicated by a threshold probability value.

A probability value may be determined by the iterative anomaly detection program 900 based on applying verification result values of one or more programming stages to an iterative model 910 that, at a given model stage, utilizes the verification result value of a given programming stage and historical data from at least one preceding model stage (or a predetermined zeroth historical data value if there is no preceding model stage) to determine the probability value. As described herein, the iterative model may include a neural network, such as a recurrent neural network (RNN) that utilizes a forward pass scheme to process each

$$( {S}_{1}^{l} , {S}_{2}^{l} , … , {S}_{n}^{l} )$$

programming stages at separate, respective model stages of the iterative model (e.g., RNN cells) to enable a probability value to be determined based on each programming sequence. In response to a determination that a given probability value determined based on a given programming stage indicates occurrence of at least one programming anomaly, a recovery action may be performed to enable recovery of the non-volatile memory device from the at least one programming error.

Determination of programming anomaly occurrence based on a probability value that indicates whether the programming rate at the n-th programming stages is so unusual to be indicative of programming anomaly occurrence is not limited to detecting programming anomalies resulting from simply low numbers of memory cells having reached a desired verify level (e.g., underprogramming), but may also detect “unusual” programming rates indicative of other types of programming anomalies, including for example programming anomalies where memory cells are programmed to a higher verify level than desired (e.g., overprogramming). For example, an “unusual” programming rate may indicate, for at least one verification voltage (e.g., verify level) of a plurality of verification voltages, at least a threshold number of memory cells of the plurality of memory cells have a threshold voltage that is outside a reference range of threshold voltages of memory cells programmed to the at least one verification voltage. Accordingly, the iterative anomaly detection program 900 that may detect programming anomalies in an iterative programming operation based on determining whether the programming rate at the n-th programming stage is excessively unusual may enable detecting (and thus recovering from) a greater range of programming anomalies than, for example, programming anomalies corresponding to a naïve cells count. Because the iterative anomaly detection program 900 enables detection, and thus recovery from, a greater of programming anomalies, the reliability of a memory device at which the iterative anomaly detection program 900 is performed with the iterative programming operation 800 may be improved without loss of capacity or performance of the memory device, thereby improving the functionality of the memory device.

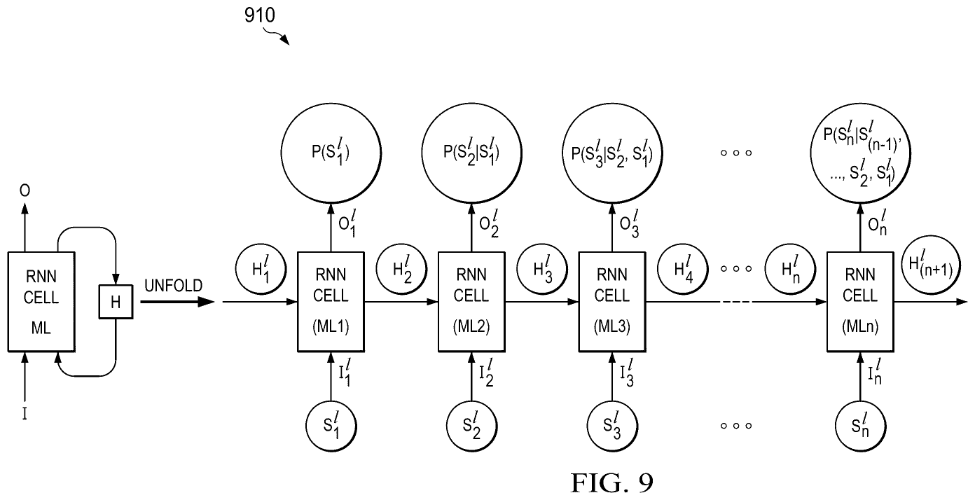

FIG. 9 illustrates a network structure of an iterative model 910 that includes a recurrent neural network (RNN) of an iterative model of an iterative anomaly detection program, according to some example embodiments.

In some example embodiments, the iterative model 910 that is performed by the iterative anomaly detection program 900 includes a neural network model, for example a recurrent neural network (RNN), that enables on-line machine learning detection of at least one programming anomaly during (e.g., prior to the final programming stage of) an iterative programming operation 800 to enable programming correction. Such an iterative model 910 (e.g., a neural network such as an RNN) may be trained to generate, at an n-th forward pass (e.g., an n-th model stage MLn, an n-th node, an n-th cell, etc.), an output indicating an n-th probability value (e.g., a negative log-likelihood as indicating a negative log-likelihood that the 1 to n-th programming stages of an iterative programming operation are free from any programming anomalies).

Referring to FIG. 9, an RNN iterative model 910 may include a repeating structure using a specific node or cell ML illustrated on the left side of FIG. 9. A structure illustrated on the right side of FIG. 9 may represent that a recurrent connection of the RNN iterative model 910 illustrated on the left side is unfolded (or unrolled). The term “unfolded” means that the RNN is written out or illustrated for the complete or entire sequence including all nodes (e.g., cells, model stages, etc.) ML1 to MLn.

In the RNN iterative model 910 in FIG. 9, I represents an input of the RNN. For example,

$$I {n}_{l}^{}$$

In maybe an input at time step “n” (or pulse index “n”, or in response to programming stage “n”, or the like) and associated with a particular l-th verification voltage “V^{l}” at time step “n” (or pulse index “n”, or in response to programming stage “n”, or the like). In the RNN in FIG. 9, H represents a hidden state. For example,

$${H}_{n}^{l}$$

may be a hidden state at a time step “n” (or pulse index “n”, or in response to programming stage “n”, or the like) and associated with a particular l-th verification voltage “V^{l}” at time step “n” (or pulse index “n”, or in response to programming stage “n”, or the like). The hidden state may be calculated based on a previous hidden state at a previous step (model stage) and an input at a current step (model stage). For example, in some example embodiments, an n-th hidden state at an n-th model stage MLn may be determined (e.g., at the prior (n−1)th model stage ML(n−1)) as

$${H}_{n}^{l} = f ( {UI}_{n} + {WH}_{n - 1}^{l} ) ,$$

where U and W may be weights and/or biases which may be determined based on training the RNN iterative model 910 as described herein. For example, the function f may be usually a nonlinearity function such as tanh or RELU.

$${H}_{1}^{l} ,$$

which is required to calculate a hidden state

$${H}_{2}^{l}$$

at the first model stage ML1, may be typically initialized to an initial value having all zeroes.

In the RNN iterative model 910 in FIG. 9, O represents an output of the RNN. For example,

$${O}_{n}^{l}$$

may be an output at time step “n” (or pulse index “n”, or in response to programming stage “n”, or the like) and associated with a particular l-th verification voltage “VW” at time step “n” (or pulse index “n”, or in response to programming stage “n”, or the like), respectively. In some example embodiments, O may be a probability value that indicates a likelihood associated with at least one programming anomaly in an iterative programming operation. In some example embodiments,

$${O}_{n}^{l}$$

is one or more parameters of a probability distribution (e.g., a conditional probability distribution) that may be applied to generate a probability distribution that further indicates the probability value (e.g., indicates a conditional probability for a given n-th time step or programming stage and associated with a particular 1-th verification voltage “V^{l}” that may be used, for example based on multiplication with other conditional probabilities (e.g., a multiplication product of the 1 to n-th conditional probabilities), to calculate an n-th probability value) based, for example, on the input value

$${I}_{n}^{l}$$

(which as shown, may include an n-th verification result value

$${S}_{n}^{l}$$

that is generated at the n-th programming stage of the iterative programming operation 800 and is associated with a particular l-th verification voltage “V^{l}”). For example, as shown in FIG. 9,

$${O}_{n}^{l}$$

may be an n-th conditional probability value

$$P ( {S}_{n}^{l} \vert {S}_{n - 1}^{l} , {S}_{n - 2}^{l} , … , {S}_{1}^{l} )$$

or may include information that is used to calculate same, and as described herein the calculated n-th conditional probability value

$$P ( {S}_{n}^{l} \vert {S}_{n - 1}^{l} , {S}_{n - 2}^{l} , … , {S}_{1}^{l} )$$

may be used to calculate an n-th probability value

$${P}_{n}^{l} = P ( {S}_{n}^{l} , {S}_{n - 1}^{l} , {S}_{n - 2}^{l} , … , {S}_{1}^{l} ) .$$

In another example,

$${O}_{n}^{l}$$

may be the n-th probability value

$$P ( {S}_{n}^{l} , {S}_{n - 1}^{l} , {S}_{n - 2}^{l} , … , {S}_{1}^{l} )$$

or may include information that used to calculate same.

In the RNN iterative model 910 in FIG. 9, the hidden state may be a “memory” of the RNN iterative model 910. In other words, the RNN iterative model 910 may have a “memory” which captures information about what has been calculated so far (e.g., in previous model stages). The hidden state Hₙ may capture information about what happened in all the previous time steps (e.g., the previous model stages ML1 to ML(n−1)). The output

$${O}_{n}^{l}$$

ma be calculated based on the memory at the current time step n and associated with a particular l-th verification voltage “V^{l}” at the current time step n. In addition, unlike a traditional neural network, which uses different parameters at each layer, the RNN may share the same parameters, such as weights and/or biases (e.g., U and W in FIG. 9) across all time steps (e.g., across all model stages ML1 to MLn). This may represent the fact that the same task may be performed at each step, just with different inputs. This may greatly reduce the total number of parameters required to be trained or learned, thereby improving efficiency of the neural network and thus improving efficiency and/or performance of services and/or applications that are performed, executed or processed by a device implementing the neural network.

Accordingly, the efficiency and/or performance of the iterative anomaly detection program, and one or more devices and/or systems implementing same may be improved based on utilizing a neural network such as the RNN shown in FIG. 9 as an iterative model to determine a probability value associated with occurrence of at least one programming anomaly in a sequence of 1 to n-th programming stages of the iterative programming operation based on both an n-th verification result value

$${S}_{n}^{l}$$

indicating a number of memory cells of the plurality of memory cells having a threshold voltage Vth that is equal to or greater than a particular l-th verification voltage “V^{l}” at the n-th programming stage (e.g., in the input Iₙ), and n-th historical data

$${H}_{n}^{l}$$

associated with at least an (n−1)-th programming stage of the iterative programming operation and the particular l-th verification voltage “V^{l}”. While FIG. 9 illustrates a RNN iterative model 910 where the 1 to n-th model stages (e.g., RNN cells) calculate an output

$${O}_{n}^{l}$$

associated with the particular l-th verification voltage “V^{l}”, that may be an n-th conditional probability value

$$P ( {S}_{n}^{l} \vert {S}_{n - 1}^{l} , {S}_{n - 2}^{l} , … , {S}_{1}^{l} )$$

associated with the particular 1-th verification voltage “V^{l}” or may include information that is used to calculate same, based on an input

$${I}_{n}^{l} ( e . g . , {S}_{n}^{l} )$$

and historical data

$${H}_{n}^{l}$$

associated with the particular 1-th verification voltage “V^{l}” example embodiments are not limited thereto.

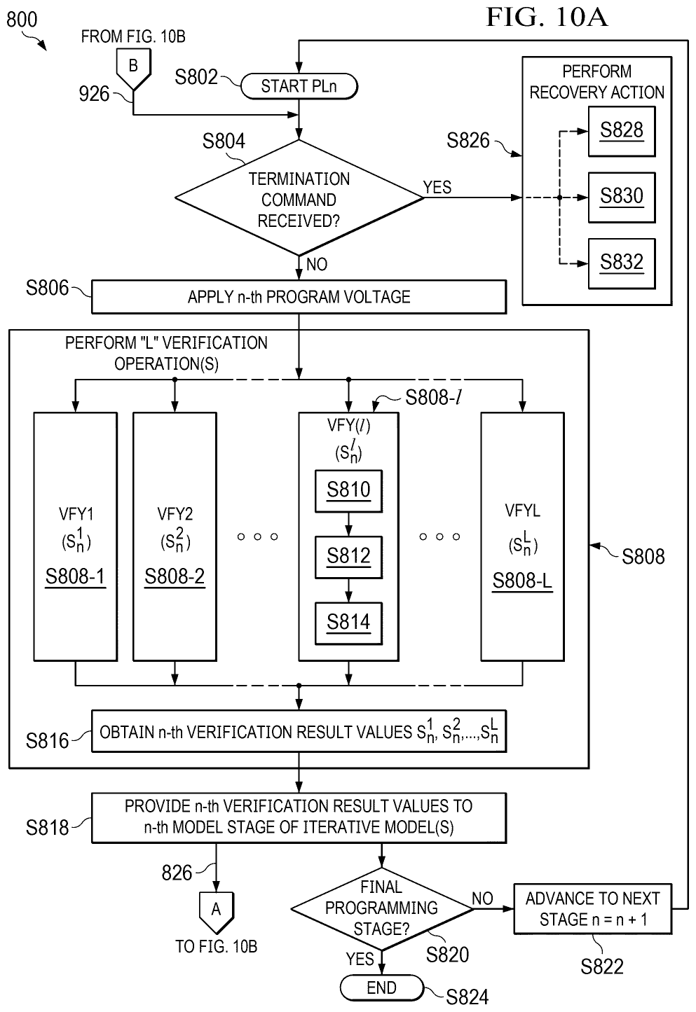

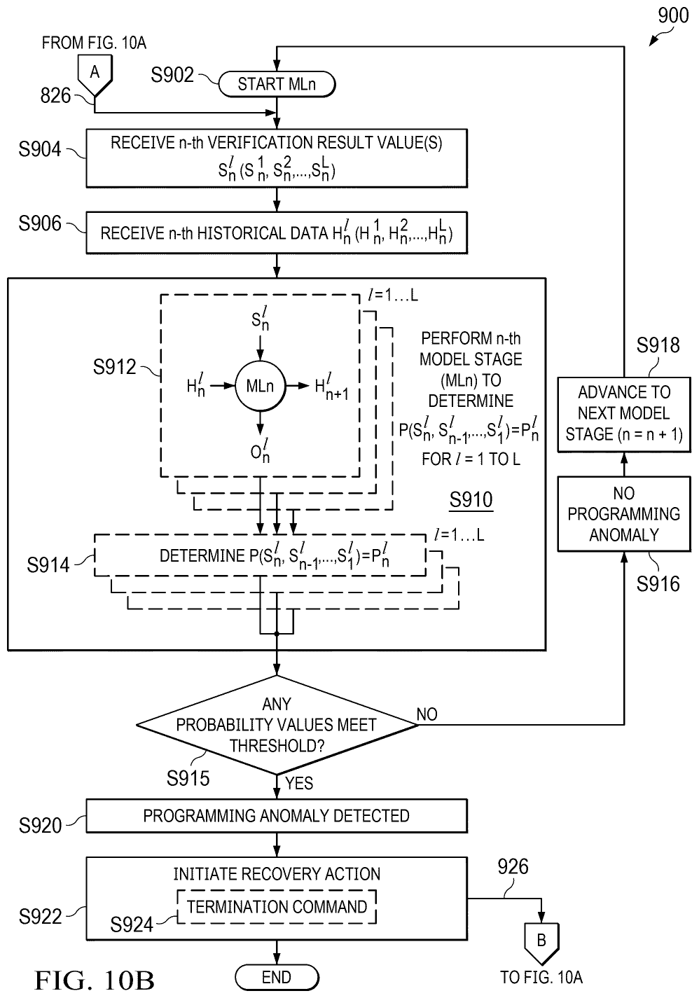

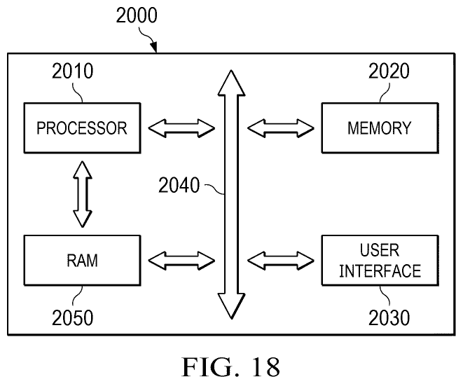

FIG. 10A is a flowchart illustrating a method of performing an iterative programming operation 800 to program a non-volatile memory device having at least a plurality of memory cells, according to some example embodiments. FIG. 10B is a flowchart illustrating a method of performing an iterative anomaly detection program 900 corresponding to the iterative programming operation of FIG. 10A, according to some example embodiments. FIG. 11 is a flowchart illustrating a method 1400 including an iterative programming operation 800 and an iterative anomaly detection program 900, according to some example embodiments. The iterative programming operation 800 shown in FIG. 11 may be the iterative programming operation 800 shown in FIG. 10A. The iterative anomaly detection program 900 shown in FIG. 11 may be the iterative anomaly detection program 900 shown in FIG. 10B. In some example embodiments, the non-volatile memory device (e.g., at least one of memory device 300, memory device 17, NVM 220, NVMS 1320a and/or 1320b) may be a NAND flash device. In some example embodiments, the non-volatile memory device (e.g., at least one of memory device 300, memory device 17, NVM 220, NVMS 1320a and/or 1320b) may be included in an electronic device (e.g., system 1000 in FIG. 1, electronic device 2000 in FIG. 18, etc.).

It will be understood that the methods shown in FIGS. 10A, 10B, and 11 may be implemented by any device, system, or the like according to any of the example embodiments, for example the system 1000 of FIG. 1, the storage device 200 of FIG. 2, the storage device 15 of FIG. 3, the memory device 300 of FIG. 4, any combination thereof, or the like, for example based on a processor thereof executing a program of instructions stored on a memory thereof.

It will be understood that the operations of the method shown in FIG. 10A may be arranged in any order and/or may be rearranged in order relative to the order shown in FIG. 10A. One or more of the operations shown in FIG. 10A may be omitted from the method shown in FIG. 10A. One or more operations may be added to the method shown in FIG. 10A. It will be understood that the operations of the method shown in FIG. 10B may be arranged in any order and/or may be rearranged in order relative to the order shown in FIG. 10B. One or more of the operations shown in FIG. 10B may be omitted from the method shown in FIG. 10B. One or more operations may be added to the method shown in FIG. 10B. It will be understood that the operations of the method shown in FIG. 11 may be arranged in any order and/or may be rearranged in order relative to the order shown in FIG. 11. One or more of the operations shown in FIG. 11 may be omitted from the method shown in FIG. 11. One or more operations may be added to the method shown in FIG. 11.

Referring to FIGS. 10A, 10B, and 11, in some example embodiments the iterative anomaly detection program 900, performed based on an iterative programming operation 800, enables detection, including “early” detection, of one or more programming anomalies in the iterative programming operation, based on performing an iterative model 910 to determine a probability value indicating that the likelihood of at least one programming anomaly in the iterative programming operation 800 is at or greater than a threshold probability value (or, alternatively, that the likelihood of no programming anomalies in the iterative programming operation 800 less than a threshold probability value).

As described herein, a programming anomaly may include one or more operational and structural malfunctions in a non-volatile memory device, such as a NAND device, that are known to obstruct data storage already at the programming stage.

In some example embodiments, the iterative anomaly detection program provides an iterative model (e.g., algorithm) for detecting faulty programming scenarios indicating presence of at least one programming anomaly in an iterative programming operation to program a non-volatile memory device (e.g., a NAND device). Such faulty programming scenarios that may be detected by the iterative anomaly detection program may include, for example, (1) faulty NAND blocks (physical impairments), (2) extreme bit error rate after programming, (3) programming of a partially erased block, (4) program process wrongly resumed after suspension, any combination thereof, or the like, but example embodiments of faulty programming scenarios that may be detected based on performing an anomaly detection process utilizing the iterative model are not limited thereto.

The iterative model 910 of the iterative anomaly detection program 900 may enable live (e.g., during an iterative programming operation) detection of faulty programming scenarios (e.g., detection that the iterative programming operation is a faulty iterative programming operation that includes at least one programming anomaly) without any additional read operations, and allows for early correction, recovery from, and/or termination of such faulty iterative programming operations. Detecting such faulty programming scenarios may reduce, minimize, or prevent data storage errors, and therefore, increase the reliability of the non-volatile device being programmed and/or the device performing the iterative programming operation 800 and the iterative anomaly detection program 900. The iterative anomaly detection program 900 and/or a method 1400 including same in combination with the iterative programming operation 800 may be referred to as a Real-Time Anomaly Detection Scheme for non-volatile Memory Programming and Recovery algorithm (e.g., NAND Flash Memory Programming and Recovery Algorithm).

Referring now generally to the iterative programming operation 800 as shown in FIGS. 10A and 11 and further referring back to FIGS. 6-7, storing data in a NAND flash memory device via the iterative programming operation 800 may be achieved based on applying a series (sequence) of N programming pulses (program voltages of the program step) and verify operations (e.g., N programming stages PL1 to PLN) on each WL, where N may be any positive integer. The inhibit vector for each pulse (except for the first pulse) is determined by a set of one or more verify operations (verify steps) that are performed at given verification voltages {Vₗ:l ∈[L]}, where L is the number of levels above the erase level and may be any positive integer. The number of memory cells connected to a selected word line WL having a respective threshold voltage Vth above a particular verification voltage Vₗ after the n-th programming pulse (n∈[N]) is denoted by

$${S}_{n}^{l}$$

∈[N_{cells}], where N_{cells} is the number (quantity) of memory cells connected to a single selected word line WL. A programming anomaly is then detected based on determining that at least 1 to n-th programming stages of the iterative programming operation generate an improbable sequence of verification results, also referred to herein as verification result values,

$${S}_{1}^{l} , {S}_{2}^{l} , … , {S}_{n}^{l}$$

for each l∈[L].

Referring now in further detail to FIGS. 10A and 11 and further referring to FIGS. 6-7, an iterative programming operation 800 may include repeatedly (e.g., iteratively) performing a programming stage PL (e.g., program loop) at least “n” times to program a plurality of memory cells that are connected to a word line (e.g., BLK1 in FIG. 4) to a desired programming voltage, where each n-th programming stage PL includes applying an n-th program voltage PGMn to the memory cells and then performing a set of “L” verification operations VFYn, where “n” and “L” are each independently a positive integer. In some example embodiments, “n” is a positive integer that is equal to or greater than 1. In some example embodiments, an iterative programming operation has a particular (or, alternatively, predetermined) number of program loops, or programming stages, N, which is a positive integer, such that an n-th stage is one of the 1 to N-th programming stages, and thus the value of “n” may be between 1 and N. The N-th programming stage may be referred to herein as a final programming stage of the iterative programming operation 800.

As shown in FIG. 11, the iterative programming operation 800 may include repeatedly (e.g., iteratively) performing a programming stage PL, such that the iterative programming operation includes performing a sequence of at least 1 to n-th programming stages (PL1 to PLn). The description with regard to FIG. 10A is provided with regard to a given n-th stage (PLn) of an iterative programming operation 800 that includes at least 1 to n-th programming stages. But it will be understood that the method shown in FIG. 10A with regard to the n-th programming stage may be applied to any of the programming stages of the iterative programming operation 800. It will be understood that the iterative programming operation 800 shown in FIGS. 10A and 11 may be performed according to an ISPP scheme.

At S802, a given n-th programming stage PLn is started. As shown in FIG. 11, each given programming stage PL may be started in response to a particular time step “n” a pulse index “n” or the like.

At S804, a determination is made regarding whether a programming operation termination command (RC1) is received. The programming operation termination command is described further below. If so (S804=YES), then at least one recovery action is initiated at S826, which may include at least one of terminating the iterative programming operation 800 prior to completion of a final programming stage of the iterative programming operation 800 (S828), an error correction operation, which may include for example marking-up the block of the memory cell array (e.g., BLK1 in FIG. 4) that includes the selected word line and memory cells connected thereto at which the iterative programming operation 800 is being performed as a bad block, allocating a new address for the iterative programming operation (e.g., BLK2 in FIG. 4) and repeating the iterative programming operation 800 at the new allocated address (e.g., BLK2 in FIG. 4) (S830), and/or transmitting a warning signal (e.g., via a communication device such as the communication device 1140 in FIG. 1, via a display such as the display 1450 in FIG. 1, etc.) to provide an indication of the occurrence of the at least one programming anomaly to an external device, a user supported by a device performing the iterative programming operation 800, or the like (S832).

If no programming operation termination command is received (S804=NO), then at S806 the n-th programming step performs a program step of the n-th programming stage (e.g., the n-th program step). As shown in FIG. 7, the program step of the n-th programming stage (PLn) includes applying an n-th program voltage Vpgm (e.g., PGMn) to a selected word line connected to a particular plurality of memory cells of the non-volatile memory device (e.g., BLK1 of memory cells as shown in FIGS. 4 and 5A), such that the n-th program voltage PGMn is applied to the particular plurality of memory cells. Applying the n-th program voltage PGMn may change threshold voltages Vth of the memory cells.

At S808, the iterative programming operation 800 performs a verify step that includes performing a set S808-1 to S808-L of “L” verification operations associated with separate, respective particular verification voltages V¹, V², . . . , V^{L} on the plurality of memory cells (e.g., BLK1) that received the n-th programming voltage PGMn at S806 to generate, for each particular verification voltage V^{l} where “l” is a positive integer between 1 and L, an n-th verification result value

$${S}_{n}^{l}$$

indicating a number of memory cells of the plurality of memory cells (e.g., BLK1) having a threshold voltage Vth that is equal to or greater than the particular verification voltage V^{l} at the n-th programming stage PLN.

At S810, the l-th verification operation S808-l includes applying a particular l-th verification voltage V^{l} to the selected word line WL connected to the memory cells (e.g., BLK1). Referring to FIG. 4, the control logic circuitry 320 may control the voltage generator 350 to apply the particular l-th verification voltage V^{l} to the selected word line WL. At S812, the l-th verification operation includes determining the l-th threshold voltages Vth of the memory cells connected to the selected word line (e.g., via operating a ground selection line transistor GSTa and/or GSTb as shown in FIG. 5A to read the voltages of the memory cells connected to the selected word line), for example the memory cells of BLK1. At S814, the l-th verification operation S808-l includes comparing the read l-th threshold voltages Vth of the memory cells to the particular l-th verification voltage V^{l} to count the number (quantity) of the memory cells having a threshold voltage Vth that is equal to or greater than the particular l-th verification voltage V^{l}. Such a number is the l-th verification result value

$${S}_{n}^{l}$$

indicating a number of memory cells of the plurality of memory cells (e.g., BLK1) having a threshold voltage Vth that is equal to or greater than the particular verification voltage V^{l} at the n-th programming stage PLN.

At S816, the verification result values of the set of “L” verification operations S808-1 to S808-L may be collected to establish a sequence of one or more n-th verification result values

$${S}_{n}^{1} , … , {S}_{n}^{L} ,$$

where “L” may be any positive integer.

Au erein, “L” may be any positive integer, including 1, such that the set of “L” verification operations may include performing a single verification operation or performing a plurality of verification operations. In some example embodiments, where L=1, performing the set of “L” verification operations at S808 includes performing a verification operation (e.g., S808-1) associated with a particular verification voltage V^{l} on the plurality of memory cells to generate an n-th verification result value

$${S}_{n}^{1}$$

indicating a number of memory cells of the plurality of memory cells having a threshold voltage Vth that is equal to or greater than the particular verification voltage V¹ at the n-th programming stage PLn. In some example embodiments, where L is greater than 1, performing the set of “L” verification operations at S808 includes performing a plurality of verification operations S808-1 to S808-L on the plurality of memory cells to generate a plurality (e.g., of n-th verification result values

$${S}_{n}^{1} , {S}_{n}^{2} , … , {S}_{n}^{L} ,$$

wherein the plurality of verification operations (e.g., S808-l where “l” is inclusively between 1 and L) are each associated with separate, respective verification voltages V^{l} of a plurality of verification voltages V¹, V², . . . , V^{L} that are different from each other, and each separate n-th verification result value

$${S}_{n}^{l}$$

of the plurality of n-th verification result values

$${S}_{n}^{1} , {S}_{n}^{2} , … , {S}_{n}^{L} ,$$

indicates a separate number of memory cells of the plurality of memory cells having a threshold voltage Vth that is equal to or greater than a separate verification voltage V^{l} of the plurality of verification voltages V¹, V², . . . , V^{L} at the n-th programming stage PLn.

Referring to FIGS. 10A and 11, at S818 the iterative programming operation 800 provides (e.g., outputs) the n-th verification result value(s) 826

$$( e . g . , {S}_{n}^{1} , {S}_{n}^{2} , … , {S}_{n}^{L}$$

when L>2) to the iterative anomaly detection program 900, for example to be provided as an input to one or more model stages ML of one or more iterative models 910 (as indicated by the output “A” of FIG. 10A also shown in FIG. 10B). In FIG. 11, the n-th verification result value(s)

$$( e . g . , {S}_{n}^{1} , … , {S}_{n}^{L} )$$

that are provided at S818 to the iterative anomaly detection program are collectively represented as

$$“ {S}_{n}^{l} ” .$$

At S820, a determination is made regarding whether the current n-th programming stage is the final programming stage of the iterative programming operation 800. For example, where the iterative programming operation 800 is configured to have a predetermined N programming stages PL1 to PLN (where N is a particular positive integer), the determination at S820 may include a determination of whether “n” is equal to or greater than “N”. If so (S820=YES), at S824 the iterative programming operation 800 ends. If not, at S822, the iterative programming operation 800 advances to the next programming stage at the next time step, pulse index, or the like, such that the current stage is incremented from the “n-th” programming stage to the (n+1)-th programming stage. As shown in FIG. 11, a given programming stage PL may complete prior to the time step of the next programming stage, but example embodiments are not limited thereto.

Referring now generally to FIGS. 10B and 11, an iterative anomaly detection program 900 of the method 1400 is configured to receive one or more process verification result values

$${S}_{n}^{l}$$

826

$$( e . g . , {S}_{n}^{1} , … , {S}_{n}^{L} )$$

that are provided at S818 at one or more programming stages of the iterative programming operation 800, and corresponding to one or more particular verification voltages, to determine a probability value associated with a likelihood of at least one programming anomaly in the iterative programming operation 800. For example, the iterative anomaly detection program 900 may determine whether a sequence of verification result values for a given verification voltage over a series of 1 to n-th programming stages

$$( {S}_{1}^{l} , {S}_{2}^{l} , … , {S}_{n}^{l} )$$

sufficiently unusual (e.g., deviant from the sequence of “standard,” non-faulty iterative programming operations) so as to be indicative of the presence of at least one programming anomaly in the iterative programming operation 800.

The iterative anomaly detection program 900 may utilize an iterative model 910 (e.g., the RNN iterative model as show in FIG. 9) configured to repeatedly perform a model stage ML based on repeatedly performing programming stages PL of the iterative programming operation 800 such that, at a given n-th model stage MLn, the iterative model processes at least one verification result value of the n-th programming stage

$${S}_{n}^{l}$$

as an input, together with historical data

$${H}_{n}^{l}$$

(e.g., a hidden state, hidden layer, etc. of a RNN iterative model 910) which includes information associated with (e.g., is generated based on) at least an (n−1)-th programming stage (PL(n−1)) of the iterative programming operation 800 to determine an n-th probability value

$$“ {P}_{n}^{l} ”$$

indicating a probability associated with occurrence of at least one programming anomaly in the 1 to n-th programming stages of the iterative programming operation 800.

In some example embodiments, the iterative model 910 may, at each model stage ML, establish a probability distribution (e.g., a conditional probability distribution), for example based on determining parameters of the probability distribution that solves for probability value as a function of at least the verification result value, and further determine the n-th probability value indicated by the probability distribution based on the n-th verification result value Sn. The n-th probability value may then be processed (e.g., compared to a threshold probability

$${S}_{n}^{l} .$$

value corresponding to the n-th programming stage and/or the n-th model stage) to determine whether the n-th probability value indicates an occurrence (e.g., a presence) of at least one programming anomaly in the 1 to n-th programming stages PL1 to PLn of the iterative programming operation 800.

For example, for a given l-th verification voltage V^{l} the iterative model 910 may model a density of a sub-sequence of 1 to n-th verification result values

$${S}_{1}^{l} , {S}_{2}^{l} , … , {S}_{n}^{l}$$

of the 1 to n-th programming stages using an auto-regressive model, which may be learned with a RNN (see illustration in FIG. 9). Each time-step of the iterative model (e.g., time step of the RNN) may correspond to a single programming pulse and its accompanying verify operations (e.g., a single programming stage PL of the iterative programming operation 800.

The descriptions herein may describe the iterative model as a neural network, including for example an RNN, but it will be understood that example embodiments are not limited thereto and may include any iterative model and/or algorithm configured to iteratively (repeatedly) perform model stages that each utilize a verification result value of a corresponding programming stage (PLn) and historical data associated with at least one preceding programming stage (PL(n−1)) of the iterative programming operation 800 to determine an n-th probability value indicating a probability associated with occurrence of at least one programming anomaly in the 1 to n-th programming stages of the iterative programming operation 800.

Referring now in further detail to FIGS. 10B and 11 in view of FIG. 9, the iterative anomaly detection program 900 may include repeatedly (e.g., iteratively) performing a model stage ML of an iterative model 910, such that the iterative anomaly detection program 900 includes performing a sequence of at least 1 to n-th model stages (ML1 to MLn). As shown, the iterative anomaly detection program 900 may perform at least an n-th model stage MLn of an iterative model 910 that utilizes the n-th verification result value(s)

$$( e . g . , {S}_{n}^{l} )$$

generated at the n-th programming stage PLn of the iterative programming operation 800 and n-th historical data

$$( e . g . , {H}_{n}^{l} )$$

associated with at least an (n−1)-th programming stage PL(n−1) of the iterative programming operation 800 to determine an n-th probability value, which may be represented by

$$“ {P}_{n}^{l} ”$$

in FIG. 11, indicating a probability associated with occurrence of at least one programming anomaly in the 1 to n-th programming stages PL1 to PLn of the iterative programming operation 800.

The description with regard to FIG. 10B is provided with regard to a given n-th model stage (MLn) of an iterative model 910 of an iterative anomaly detection program 900 that includes at least 1 to n-th model stages, but it will be understood that the method shown in FIG. 10B with the regard to the n-th model stage MLn may be applied to any of the model stages of the iterative model 910 of the iterative anomaly detection program 900.

At S902, performing the n-th model stage of the iterative model 910 of the iterative anomaly detection program 900 may include receiving at least one n-th verification result value

$${S}_{n}^{l}$$

corresponding to a particular at least one verification voltage (V^{l}) based on operation of the n-th programming stage PLn of the iterative programming operation 800 (as indicated by the input “A” of FIG. 10B corresponding to the output “A” shown in FIG. 10A and as represented in FIG. 11 as providing

$$“ {S}_{n}^{l} ”$$

at 826 from the n-th programming stage PLn of the iterative programming operation 800 to the n-th model stage MLn of the iterative anomaly detection program 900). For example, where the number of verification voltages “L” in the iterative programming operation is greater than 1, the receiving at S902 may include receiving a sequence of verification result values

$${S}_{n}^{1} , {S}_{n}^{2} , … , {S}_{n}^{L}$$

for each of the verification voltages 1 to L (represented in FIG. 11 by

$$“ {S}_{n}^{l} ” ) ,$$

but example embodiments are not limited thereto, and in some example embodiments a single n-th verification result value

$$( e . g . , {S}_{n}^{l} )$$

may be received at S904 (represented in FIG. 11 by

$$“ {S}_{n}^{l} ” ) .$$

At S906, the n-th model stage of the iterative model of the iterative model 910 may include receiving (e.g., loading from a previous model stage of the iterative model 910 and/or a memory device) at least one n-th historical data

$${H}_{n}^{l}$$

associated with at least an (n−1)-th programming stage PL(n−1) of the iterative programming operation 800 and represented in FIG. 11 by

$$“ {H}_{n}^{l} ” .$$

As described herein, the n-th historical data

$${H}_{n}^{l}$$

may be generated at a previous (n−1)-th model stage of the iterative model 910 so as to provide a “memory” of previous model stages (e.g., at least the (n−1)-th model stage ML(n−1)) in the operation of the n-th model stage. For example, where the number of verification voltages “L” in the iterative programming operation is greater than 1, the receiving at S906 may include receiving a sequence of historical data values (e.g., hidden states)

$${H}_{n}^{1} , {H}_{n}^{2} , … , {H}_{n}^{L}$$

(collectively represented in FIG. 11 by

$$“ {H}_{n}^{l} ” )$$

for each of the verification voltages 1 to L, but example embodiments are not limited thereto, and in some example embodiments a single n-th historical data result value

$$( e . g . , {H}_{n}^{l} )$$

may be received at S906. S906 may be represented in FIG. 11 as the n-th model stage MLn of the iterative model of the iterative model 910 receiving n-th historical data

$$“ {H}_{n}^{l} ” .$$

It will be understood that, as described with reference to FIG. 9,

$${H}_{1}^{l}$$

(e.g., each of

$${H}_{n}^{1} , {H}_{n}^{2} , … , {H}_{n}^{L} )$$

which is received at S906 as part of the first model stage ML1, may be stored in a memory of a device implementing the first model stage ML1 and may be typically initialized to an initial value which may be a value having all zeroes.

At S910, the iterative model 910 of the iterative anomaly detection program 900 may execute (e.g., perform) the node S912 (e.g., cell) of the n-th model stage MLn. Each node may utilize at least one n-th verification result value

$${S}_{n}^{l}$$

(received at S904) as an input to the node and may further use at least one n-th historical data value

$${H}_{n}^{l}$$

(received at S906) to generate at least one output value

$${O}_{n}^{l}$$

that may include determining at least one n-th probability value

$${P}_{n}^{l} .$$

Such a process may be performed for each of the l-th verification voltages 1 to L (and thus using the corresponding n-th verification result values

$${S}_{n}^{1} , … , {S}_{n}^{L}$$

and historical data values

$${H}_{n}^{1} , … , {H}_{n}^{L}$$

so as to determine n-th probability values

$${P}_{n}^{1} , … , {P}_{n}^{L} ,$$

respectively.

Referring to an iterative model of the iterative anomaly detection program 900 that includes an RNN such as shown in FIG. 9, and as shown in FIG. 11, an input of the iterative model 910 at time-step n∈{1, . . . N} may be the result of the verification operation(s) in the previous programming stage PL(n) which are received at S904 as at least one verification result value

$${S}_{n}^{l} ,$$

although example embodiments are not limited thereto. In some example embodiments, where the iterative model includes an RNN, the n-th historical data

$${H}_{n}^{l}$$

may be a hidden stage from the previous iteration of the iterative model (e.g., the previous (n−1)-th model stage). The output of the iterative model 910 at a given time-step (e.g., the output of the n-th model stage MLn) may be, or may be used to determine, an n-th conditional probability value, where the n-th conditional probability value indicates a probability of the value of the n-th verification result value

$${S}_{n}^{l} ,$$

given the values of some or all of the 1 to (n−1)-th verification result values generated in some or all of the 1 to (n−1)-th programming stages PL1 to PL(n−1) of the iterative programming operation 800. Such an n-th conditional probability value may be expressed as Equation (1):

$$P ( {S}_{n}^{l} \vert {S}_{n - 1}^{l} , {S}_{n - 2}^{l} , … , {S}_{1}^{l} ) \qquad ( 1 )$$

Restated, an n-th model stage of the iterative model 910, performed in response to the n-th stage verification operation(s) of the n-th programming stage, may use the output of the iterative model (e.g., RNN) from the previous (n−1)-th model stage (e.g., as a hidden state, hidden layer, etc.) to calculate the conditional likelihood of the n-th verification result value

$${S}_{n}^{l}$$

(e.g., the likelihood that such a verification result value occurs in an iterative programming operation that does not include any programming anomalies, given the verification result values of previous programming stages) as shown in Equation (1) for each of the one or more verification voltages “L”.

At S914, the iterative anomaly detection program 900 determines the n-th probability value

$${P}_{n}^{l}$$

based on the output of the n-th model stage of the iterative model 910. In some example embodiments, the output of the n-th model stage of the iterative model 910 at S912 is the n-th probability value, and S914 is omitted as a separate operation. In some example embodiments, the output of the n-th model stage at S912 is an n-th conditional probability value as shown in Equation (1) or is an output that is used to determine an n-th conditional probability value as shown in Equation (1), and at S914 the iterative anomaly detection program 900 may utilize the n-th conditional probability value of the iterative model 910 to calculate the likelihood of the sub-sequence

$$P ( {S}_{n}^{l} , {S}_{n - 1}^{l} , {S}_{n - 2}^{l} , … , {S}_{0}^{l} )$$

as the n-th probability value

$${P}_{n}^{l} ( e . g . , {P}_{n}^{l} = P ( {S}_{n}^{l} , {S}_{n - 1}^{l} , {S}_{n - 2}^{l} , … , {S}_{1}^{l} ) )$$

as shown in Equation (2):

$$P ( {S}_{n}^{l} , {S}_{n - 1}^{l} , {S}_{n - 2}^{l} , … , {S}_{1}^{l} ) = P ( {S}_{n}^{l} \vert {S}_{n - 1}^{l} , {S}_{n - 2}^{l} , … , {S}_{1}^{l} ) * P ( {S}_{n - 1}^{l} \vert {S}_{n - 2}^{l} , … , {S}_{1}^{l} ) * … * P ( {S}_{1}^{l} ) \qquad ( 2 )$$

As shown in Equation (2), the n-th probability value

$${P}_{n}^{l}$$

may be determined based on the multiplication product of the conditional probability values determined based on performing each of the 1 to n-th model stages ML1 to MLn. It will be understood that a given conditional probability value calculated at a given model stage (e.g., based on the output at S912) may be stored in a memory (e.g., a non-transitory storage device), such that, at S914 of an n-th model stage MLn S910, the iterative anomaly detection program 900 may, in response to or based on determining the n-th conditional probability value

$$P ( {S}_{n}^{l} \vert {S}_{n - 1}^{l} , {S}_{n - 2}^{l} , … , {S}_{1}^{l} ) ,$$

load the 1 to (n−1)-th conditional probability values

$$P ( {S}_{n - 1}^{l} \vert {S}_{n - 2}^{l} , … , {S}_{1}^{l} ) * … * P ( {S}_{1}^{l} )$$

from a memory (e.g., a memory of a device implementing the iterative anomaly detection program 900) and determine the n-th probability value

$${P}_{n}^{l} = ( {S}_{n}^{l} , {S}_{n - 1}^{l} , {S}_{n - 2}^{l} , ... , {S}_{1}^{l} )$$

according to Equation (2). It will be understood that, at the 1^{st} model stage (n=1), the n-th conditional probability value

$$P ( {S}_{1}^{l} )$$

may be the same as the n-th probability value.

Restated, at S914 an n-th model stage of the iterative model 910, performed in response to the n-th stage verification operation(s) of the n-th programming stage, may use the output of the iterative model (e.g., RNN) from the previous (n−1)-th model stage (e.g., as a hidden state, hidden layer, etc.) to calculate the n-th probability value

$$( {P}_{n}^{l} = P ( {S}_{n}^{l} , {S}_{n - 1}^{l} , {S}_{n - 2}^{l} , ... , {S}_{1}^{l} ) )$$

indicating a likelihood of the sub-sequence

$$( {S}_{n}^{l} , {S}_{n - 1}^{l} , {S}_{n - 2}^{l} , ... , {S}_{0}^{l} )$$

(e.g., the likelihood that such a sequence of verification result values occurs in an iterative programming operation 800 that does not include any programming anomalies).

Still referring to S910, in some example embodiments, where the number of verification voltages “L” in the iterative programming operation is greater than 1, such that a plurality of verification operations S808-1 to S808-L are performed in n-th programming stage as shown in FIG. 10A to generate a plurality of n-th verification result values

$${S}_{n}^{1} , {S}_{n}^{2} , ... , {S}_{n}^{L} ,$$

such that the receiving at S902 may include receiving a sequence of verification result values

$${S}_{n}^{1} , {S}_{n}^{2} , ... , {S}_{n}^{L}$$

for each of the verification voltages 1 to L, the performing of the n-th model stage may include, at S912, the iterative anomaly detection program 900 may include one or more iterative models 910 configured to generate a plurality of n-th probability values, based on applying separate n-th verification result values that correspond to separate “L” verification voltages to the one or more iterative models such that S910 generates a plurality of “L” probability values

$${P}_{n}^{1} , ... , {P}_{n}^{L}$$

as

$$P ( {S}_{n}^{1} , {S}_{n - 1}^{1} , {S}_{n - 2}^{1} , ... , {S}_{1}^{1} ) , ... , P ( {S}_{n}^{L} , {S}_{n - 1}^{L} , {S}_{n - 2}^{L} , ... , {S}_{1}^{L} ) ,$$

for example based on performing the above-noted operations at S912 and S914 for each of the separate 1 to L verification voltages.

In some example embodiments, an n-th model stage of the iterative model 910 may use a sequence of verification result values

$${S}_{n}^{1} , {S}_{n}^{2} , ... , {S}_{n}^{L}$$

as an input to a single node at S910 to generate an output that is used at S912 to determine a plurality of “L” probability values

$${P}_{n}^{1} , ... , {P}_{n}^{L}$$

as

$$P ( {S}_{n}^{1} , {S}_{n - 1}^{1} , {S}_{n - 2}^{1} , ... , {S}_{1}^{1} ) , ... , P ( {S}_{n}^{L} , {S}_{n - 1}^{L} , {S}_{n - 2}^{L} , ... , {S}_{1}^{L} ) ,$$

thereby performing a single iterative model 910 that generates the plurality of n-th probability values based on utilizing the plurality of n-th verification result values and historical data associated with the plurality of verification voltages in at least the (n−1)-th programming stage of the iterative programming operation. In some example embodiments, the iterative model 910 is actually a plurality of iterative models 910 that each generate a separate n-th probability value of the plurality of n-th probability values, wherein each n-th model stage of each separate iterative model utilizes a separate n-th verification result value of the plurality of n-th verification result values

$${S}_{n}^{1} , {S}_{n}^{2} , ... , {S}_{n}^{L}$$

that is associated with a particular verification voltage of the plurality of verification voltages and separate historical data associated with the particular verification voltage in at least the (n−1)-th programming stage of the iterative programming operation. In such example embodiments, the executing at S912 may include implementing an n-th model stage node of multiple separate iterative models 910 in parallel to generate separate outputs that are processed in parallel to generate a plurality of “L” probability values

$${P}_{n}^{1} , ... , {P}_{n}^{L}$$

as

$$P ( {S}_{n}^{1} , {S}_{n - 1}^{1} , {S}_{n - 2}^{1} , ... , {S}_{1}^{1} ) , ... , P ( {S}_{n}^{L} , {S}_{n - 1}^{L} , {S}_{n - 2}^{L} , ... , {S}_{1}^{L} )$$

### at S914.

In some example embodiments, the output of a given model stage node at S912 is an n-th probability value, such that S914 is omitted. In some example embodiments, the output of a given n-th model stage node at S912 is used at S914 to determine the n-th probability value.

In some example embodiments, determining an n-th probability value

$$( e . g . , P ( {S}_{n}^{l} , {S}_{n - 1}^{l} , {S}_{n - 2}^{l} , ... , {S}_{1}^{l} ) )$$

at S914 includes determining an n-th conditional probability distribution based on performing at least the n-th model stage (e.g., S910) of the iterative model, where the n-th conditional probability distribution indicating a distribution of probability values corresponding to verification result values, and determining a probability value indicated by the n-th conditional probability distribution that corresponds to an n-th verification result value as the n-th probability value.

For example, in some example embodiments, the n-th conditional probability value

$$P ( {S}_{n}^{l} \vert {S}_{n - 1}^{l} , {S}_{n - 2}^{l} , … , {S}_{1}^{l} )$$

may be modeled as a Beta-Binomial distribution B(N_{cells},α,β) which may describe the probability of a variable to have values between 0 and N. The Beta-Binomial distribution may be defined by two parameters, α and β (also referred to herein as first and second parameters of the Beta-Binomial distribution) as shown in Equation (3) below:

$${P}_{α , β , N} ( x ) = ( \begin{matrix}N \\ x\end{matrix} ) \frac{B ( x + α , N - x + β )}{B ( α , β )} \qquad ( 3 )$$

In Equation (3) “N” is the number of memory cells connected to the selected word line (e.g., the number of memory cells in BLK1), which may be a predetermined value stored in a memory device and accessed by a device implementing the iterative anomaly detection program 900, and “x” is the n-th verification result value generated at the n-th programming stage for a particular verification voltage,

$${S}_{n}^{l} .$$

Accordingly, the Beta-Binomial distribution P_{α,β, N}(x) as shown in Equation (3) corresponds to the n-th conditional probability value

$$P ( {S}_{n}^{l} \vert {S}_{n - 1}^{l} , {S}_{n - 2}^{l} , … , {S}_{1}^{l} )$$

as shown in Equation (1), that is the probability of

$${S}_{n}^{l}$$

(e.g., the probability that the iterative programming operation includes or does not include at least one programming anomaly) given the previous verification result values of

$${S}_{n - 1}^{l} , {S}_{n - 2}^{l} , … , {S}_{1}^{l}$$

of the previous programming stages 1 to (n−1) of the iterative programming operation 800. Such an n-th conditional probability value may further be utilized to determine an n-th probability value that indicates a probability that at least one programming anomaly has (or has not) occurred during at least 1 to n-th programming stages PL1 to PLn of the iterative programming operation 800, as shown in Equation (2). Thus, based on the n-th verification result value

$${S}_{n}^{l}$$

being generated at the n-th programming stage of the iterative programming operation 800, the n-thE verification result value

$${S}_{n}^{l}$$

may be inserted as “x” into P_{α,β, N}(x) according to Equation (3) to determine P_{α,β,N}(x) as indicating the likelihood of

$${S}_{n}^{l}$$

given the previous verification result values of

$${S}_{n - 1}^{l} , {S}_{n - 2}^{l} , … , {S}_{1}^{l} ,$$

and the resultant determined P_{α,β,N} (x) may be applied as the n-th conditional probability value

$$P ( {S}_{n}^{l} \vert {S}_{n - 1}^{l} , {S}_{n - 2}^{l} , … , {S}_{1}^{l} )$$

together with the 1 to (n−1)-th conditional probability values

$$P ( {S}_{n - 1}^{l} \vert {S}_{n - 2}^{l} , … , {S}_{1}^{l} ) , … , P ( {S}_{1}^{l} )$$

which may be loaded from a memory (e.g., a memory of a device implementing the iterative anomaly detection program 900) to determine the n-th probability value at Equation (2) indicating the likelihood (e.g., log-likelihood) of the sequence of determined verification result values of

$${S}_{n}^{l} , {S}_{n - 1}^{l} , {S}_{n - 2}^{l} , … , {S}_{1}^{l} ,$$

for example the likelihood that such a sequence (e.g., sub-sequence) occurs in an iterative programming operation 800 that does not include any programming anomalies.

In some example embodiments where the conditional probability value used to determine the probability value is modeled as a conditional probability distribution, for example a Beta-Binomial distribution as shown in at least Equation (3), the iterative model (e.g., RNN) may be configured to, at S912, generate, as the output

$${O}_{n}^{l}$$

of a given n-th model stage (MLn), the α and β parameters of the conditional probability distribution (e.g., the Beta-Binomial distribution as shown in Equation (3)). The α and β parameters may then be applied to the Beta-Binomial distribution (in addition to the known value N of the number of memory cells connected to the selected word line, which may be accessed from a memory, storage device, o the like), and the n-th verification result value

$${S}_{n}^{l}$$

may then be applied to the Beta-Binomial distribution as “x” to determine P_{α,β,N}(x) as the n-th conditional probability value which corresponds to (e.g., equals) the conditional probability

$$P ( {S}_{n}^{l} \vert {S}_{n - 1}^{l} , {S}_{n - 2}^{l} , … , {S}_{1}^{l} ) .$$

The overall n-th probability value

$${P}_{n}^{l} = P ( {S}_{n}^{l} , {S}_{n - 1}^{l} , {S}_{n - 2}^{l} , … , {S}_{1}^{l} )$$

(indicating an overall probability of anomaly occurrence (or non-occurrence) in the 1 to n-th programming stages of the iterative programming operation 800) may further be determined using the n-th conditional probability value and previous conditional probability values (e.g., 1 to (n−1)-th conditional probability values) according to Equation (2), and such an overall probability may be applied by the iterative anomaly detection program as the n-th probability value determined at S914 for a given l-th verification voltage V^{l} and applied at S915 to determine whether a programming anomaly has occurred in the iterative programming operation 800, but example embodiments are not limited thereto.

In some example embodiments, the iterative model 910 includes a recurrent neural network (RNN) that is configured to perform an n-th forward pass operation at S912 (e.g., based on executing an RNN node, or RNN cell) to generate an n-th output

$${O}_{n}^{l}$$

of the RNN that corresponds to (e.g., equals or may be processed at S914 to determine) the n-th probability value based on using at least one n-th verification result sample as an n-th input and at least one historical data value associated with at least the (n−1)-th programming stage as an n-th hidden layer that is generated based on the RNN performing an (n−1)-th forward pass operation prior to performing the n-th forward pass operation. For example, the iterative model 910 may include neural network, such as an RNN, which may have three sets of weights, Wₕᵢ, Wₕₕ and Wₒₕ, as well as a two sets of biases. bₕᵢ and bₕₕ. At each time-step “n”, or n-th model stage, of the RNN, the hidden layer may be calculated for the next (e.g., (n+1)-th) model stage using the weights and biases as shown in Equation (4):

$${H}_{n + 1}^{l} = tanh ( {W}_{hi} {x}_{n} + {b}_{hi} + {W}_{hh} {H}_{n}^{l} + {b}_{hh} ) \qquad ( 4 )$$

In Equation (4) xₙ is the n-th verification result value

$${S}_{n}^{l}$$

indicating a number of memory cells of the plurality of memory cells having a threshold voltage Vth that is equal to or greater than a particular l-th verification voltage V^{l} at the n-th programming stage, and

$${H}_{n}^{l}$$

is the hidden layer calculated at the previous (n−1)-th time step (e.g., (n−1)-th model stage) of the RNN. At the first time step, the

$${H}_{n}^{l}$$

used to calculate

$${H}_{1}^{l}$$

may be an initial value accessed from a memory device, and such initial value may be zero. The weights Wₕᵢ, Wₕₕ and Wₒₕ, and biases bₕᵢ and bₕₕ may be determined during a process to train the RNN as described herein.

The iterative model 910, at a given n-th model stage (e.g., at an n-th RNN cell of the RNN at S912), may calculate an output that includes the parameters

$${α}_{n}^{l} and {β}_{n}^{l}$$

which determine the conditional probability density for the expected number of cells with threshold voltage at or above the verification voltage V^{l} after the nth programming pulse (e.g., P_{α,β,N}(x) as shown in Equation (3)) based on performing a linear transformation of

$${H}_{n}^{l} .$$

In more detail,

$${H}_{n}^{l}$$

is a vector of size M, which is the size of the hidden layer

$${H}_{n}^{l}$$

and which is typically much larger than twice the number of verification levels (e.g., the quantity of verification voltages “L”). This is because the hidden layer

$${H}_{n}^{l}$$

(e.g., hidden state) may be required to capture the non-linearity of the iterative model 910. By contrast, the output of a neural network (e.g., RNN) iterative model 910 at each model stage may have only 2 parameters per verification level (e.g., per “l” verification voltage). Thus, to transform

$${H}_{n}^{l}$$

into

$${α}_{n}^{l} and {β}_{n}^{l}$$

(per verification level “l”), the hidden layer

$${H}_{n}^{l}$$

may be multiplied by a matrix of size M×(2×L) to obtain a product, a vector of size 2*L may be added to such a product to obtain

$${α}_{n}^{l} and {β}_{n}^{l} ,$$

as shown in Equation (5) below:

$$[ {α}_{n}^{l} , {β}_{n}^{l} ] = {O}^{l} {H}_{n}^{l} + {c}_{l} \qquad ( 5 )$$

The weights in the matrix O^{l} and the biases cₗ in Equation (5) may be determined during a process to train the RNN as described herein.

In some example embodiments, the neural network (e.g., RNN) may be trained to determine the probability value as a negative log-likelihood and the neural network may be trained to minimize the negative log-likelihood. For example, the iterative model 910 may be a neural network (for example an RNN) which may be trained to minimize the negative log-likelihood of the sequence

$${S}_{n}^{l} , {S}_{n - 1}^{l} , … {S}_{1}^{l}$$

or to maximize the log-likelihood of the sequence

$${S}_{n}^{l} , {S}_{n - 1}^{l} , … {S}_{1}^{l} .$$

For example, the neural network (e.g., RNN) may be trained to determine the probability value as a log-likelihood and the neural network may be trained to maximize the log-likelihood of the following sequence of Equation (6):

$$log P ( {S}_{n}^{l} , ... , {S}_{1}^{l} ) = log P ( {S}_{n}^{l} \vert {S}_{n - 1}^{l} , ... , {S}_{1}^{l} ) + log P ( {S}_{n - 1}^{l} \vert {S}_{n - 2}^{l} , ... , {S}_{1}^{l} ) + … + log P ( {S}_{1}^{l} ) \qquad ( 6 )$$

Accordingly, in some example embodiments, the n-th probability value determined at S910 (e.g., at S914) may correspond to an n-th iteration of a probability distribution (e.g., a conditional probability distribution) that indicates probability values as a function of verification result values (e.g., as in Equation (3)) and has one or more distribution parameters (e.g., α and β), the n-th iteration of the probability distribution (e.g., determined at S910) having n-th values of the one or more distribution parameters of the probability distribution

$$( e . g . , {α}_{n}^{l} and {β}_{n}^{l} ) ,$$

such that the n-th output

$${O}_{n}^{l}$$

generated by the RNN based on an n-th forward pass operation at S912 includes the n-th values of the one or more distribution parameters e.g.,

$${α}_{n}^{l} and {β}_{n}^{l} ,$$

and the determining the n-th probability value at S914 includes applying the n-th values of the one or more parameters to generate the n-th iteration of the probability distribution (e.g., using Equation (3) and/or based on further applying P_{α,β,N} (x) as shown in Equation (3) into Equation (2) using 1 to (n−1)-th conditional probability values loaded from memory), and determining a probability value indicated by the n-th iteration of the probability distribution that corresponds to the n-th verification result value as the n-th probability value (e.g., applying

$${S}_{n}^{l}$$

to Equation (3)). In some example embodiments, the probability distribution may be a conditional probability distribution, for example a Beta-Binomial distribution, such that the one or more distribution parameters include first and second parameters of the Beta-Binomial distribution (e.g., α and β), but example embodiments are not limited thereto. In some example embodiments, the probability distribution is determined based on applying P_{α,β,N} (x) as shown in Equation (3) into Equation (2), and the probability value indicated the n-th iteration of the probability distribution that corresponds to the n-th verification result value as the n-th probability value (e.g., applying

$${S}_{n}^{l}$$

to Equation (3) which is then applied into Equation (2)).

Still referring to FIG. 10B, at S915 the n-th model stage of the iterative anomaly detection program 900 determines whether any n-th probability value(s) determined at S910 (e.g., a plurality of probability values

$$P ( {S}_{n}^{1} , {S}_{n - 1}^{1} , {S}_{n - 2}^{1} , … , {S}_{1}^{1} ) , … , P ( {S}_{n}^{L} , {S}_{n - 1}^{L} , {S}_{n - 2}^{L} , … , {S}_{1}^{L} )$$

at S914) at least meet (e.g., equal or exceed) a corresponding n-th threshold probability value. If not (S915=NO), at S916 the iterative programming operation 800 is determined to be free of programming anomalies at least as of the n-th programming stage MLn and at S918 the iterative model 910 advances to the next model stage (n+1). As shown in FIG. 11, based on a determination that the iterative programming operation 800 is free of programming anomalies at least as of the n-th programming stage MLn (e.g., based on none of the probability values at least meeting a corresponding n-th threshold probability value at S915), the iterative programming operation 800 may be selectively continued. At S918 the iterative model 910 advances to the next model stage (n+1). If so (S915=YES), at S920 a determination is made that at least one programming anomaly has occurred in the 1 to n-th programming stages of the iterative programming operation 800. A recovery action may then, in response, be initiated at S922, which may include, at S924, transmitting a termination command RC1 (926) that causes the iterative programming operation 800 to, at S804 in FIG. 10A of a next programming stage (e.g., (n+2)-th programming stage) stop the iterative programming operation 800 and perform one or more recovery actions at S826, including at least one of performing an error correction operation (S830), terminating the iterative programming operation 800, which may include a termination prior to completion of a final programming stage of the iterative programming operation (S828), or transmitting a warning signal to provide an indication of the occurrence of the at least one programming anomaly (S832). In some example embodiments, one or more of the recovery actions of S826 may be performed by the iterative anomaly detection program 900 at S922 without or separately from transmitting the termination command (RC1). For example, the operation at S922 may include transmitting the termination command (RC1) at S924, and the iterative programming operation 800 may, at S804 and S826, respond by terminating the iterative programming operation at S828, while the operation at S922 may further perform one or more of S830 or S832. But example embodiments are not limited thereto. In some example embodiments, one or more of the recovery actions S828, S830, or S832 may be implemented by a device that is implementing one or both of the iterative programming operation 800 or the anomaly detection program 900 (e.g., implementing method 1400), where such one or more recovery actions are performed by the device separately from the iterative programming operation 800 and/or the iterative anomaly detetion program 900.

It will be understood that, in general, the n-th probability value

$${P}_{n}^{l}$$

as determined by Equation (2)

$$( {P}_{n}^{l} = P ( {S}_{n}^{l} \vert {S}_{n - 1}^{l} , {S}_{n - 2}^{l} , … , {S}_{1}^{l} ) )$$

may indicate the probability of a sequence

$${S}_{n}^{l} , {S}_{n - 1}^{l} , {S}_{n - 2}^{l} , … , {S}_{1}^{l}$$

of the iterative programming operation 800 to be normal (free of anomalies). Then, a presence of at least one programming anomaly in the iterative programming operation 800 at S915 may include a determination that the n-th probability value

$${P}_{n}^{l}$$

is lower than some threshold (e.g., a threshold probability value). In general, if

$${P}_{n}^{l}$$

is the probability distribution for a normal (anomaly-free, fault-free, standard, etc.) iterative programming operation scenario,

$$1 - {P}_{n}^{l}$$

may indicate the probability of a presence of at least one programming anomaly in the iterative programming operation 800. However, it will be understood that example embodiments of the n-th probability value

$${P}_{n}^{l}$$

is not limited to a probability value calculated as a product of 1 to n-th conditional probability values as shown in Equation (2). For example, in some example embodiments the n-th probability value

$${P}_{n}^{l}$$

may be calculated via a different equation than Equation (2).

In some example embodiments, corresponding threshold probability values may be stored (e.g., predetermined), for example in a memory, for each of the 1 to n-th programming stages (pulse indexes) and for each of the verification voltages (e.g., verify levels) at each of the programming stages, and an n-th probability value for a given n-th programming stage and l-th verification voltage (e.g., verify level) may be compared at S915 with a corresponding threshold probability value for the given programming stage and verify level to determine whether the n-th probability value indicates occurrence of at least one programming anomaly in an iterative programming operation. The threshold probability value(s) may be empirically determined and may be stored in a look-up table, for example a look-up table stored at a memory of a device implementing the iterative anomaly detection program 900. The threshold probability values may be empirically determined to establish a decision boundary that provides a desirable false positive rate. The iterative anomaly detection program 900 may, in response to determining an n-th probability value corresponding to an n-th programming stage and l-th verify level (verification voltage) at S915, access the look-up table and determine an n-th threshold probability value also corresponding to the same n-th programming stage and l-th verify level, and further determine whether a programming anomaly has occurred in the iterative programming operation 800 based on a determination of whether the probability value at least meets the corresponding threshold probability value.

In example embodiments where a plurality of probability values

$${P}_{n}^{1} , … , {P}_{n}^{L}$$

as

$$P ( {S}_{n}^{1} , {S}_{n - 1}^{1} , {S}_{n - 2}^{1} , … , {S}_{1}^{1} ) , … , P ( {S}_{n}^{L} , {S}_{n - 1}^{L} , {S}_{n - 2}^{L} , … , {S}_{1}^{L} )$$

are determined at S914, the determination at S915 may determine that at least one programming anomaly has occurred in the 1 to n-th programming stages of the iterative programming operation 800 (e.g., S915=YES) based on determining that any (e.g., at least one) n-th probability value of the plurality of n-th probability values at least meets a corresponding n-th threshold probability value.

Based on a determination that at least one probability value

$$( e . g . , P ( {S}_{n}^{l} , {S}_{n - 1}^{l} , {S}_{n - 2}^{l} , … , {S}_{1}^{l} ) )$$

at least meets a predefined threshold value, the iterative anomaly detection program 900 may determine that at least one programming anomaly is present in the iterative programming operation. In some example embodiments, a programming anomaly that may be present in the iterative programming operation 800 may include, in example embodiments where the number of verification voltages “L” is greater than 1, and for at least one verification voltage of the plurality of verification voltages “L”, at least a threshold number of memory cells of the plurality of memory cells having a threshold voltage Vth that is outside a reference range of threshold voltages of memory cells programmed to the at least one verification voltage. The reference range may be stored at a memory device and accessed as needed.

Referring to FIG. 11, the model stages of the iterative model 910 of the iterative anomaly detection program 900 may be performed subsequently to corresponding programming stages of the iterative programming operation 800 being performed. For example, as shown in FIG. 11, while an n-th programming stage PLn may be performed at a time-step n, the corresponding n-th model stage MLn of the iterative model 910 that utilizes the n-th verification result value generated in the n-th programming stage PLn may be performed at a subsequent time step (n+1). For example, as shown, an n-th model stage of the iterative model 910 which utilizes at least one n-th verification result value generated at the n-th programming stage may be performed at least partially concurrently with performing an (n+1)-th programming stage PL(n+1) of the iterative programming operation at an (n+1)-th time step. As a result, the iterative anomaly detection program 900 may be performed without additional latency in the iterative programming operation 800, thereby providing the improved anomaly detection provided by the iterative anomaly detection program 900, and thus the improved reliability of a device implementing same, without reducing the capacity or programming performance of the device with regard to the iterative programming operation 800.

Still referring to FIG. 11, in response to a determination at the n-th model stage MLn that at least one programming anomaly is present in the iterative programming operation 800, the iterative anomaly detection program 900 may cause a termination command (RC1) to be generated and transmitted to cause the iterative programming operation 800 to be terminated early (e.g., prior to performing the next programming stage ML(n+2) after the determination), so that the iterative programming operation is terminated and recovery action(s) may be performed at S826 in FIG. 10A early, thereby improving the response and recovery performance of a device implementing method 1400.

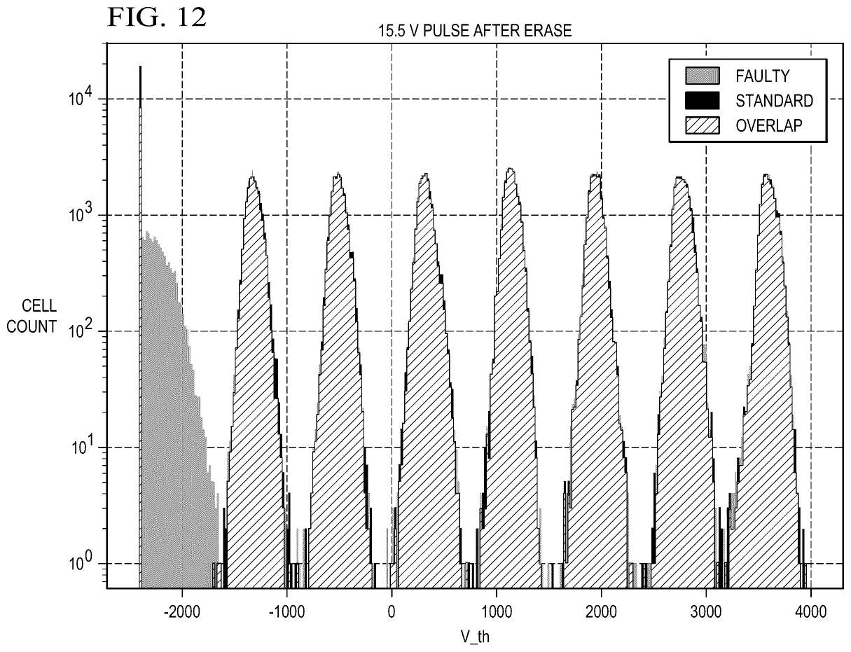

To demonstrate the effect of the inventive concepts, examples testing the ability of the iterative model to detect at least one programming anomaly in an iterative programming operation are shown in at least FIGS. 12 to 14.

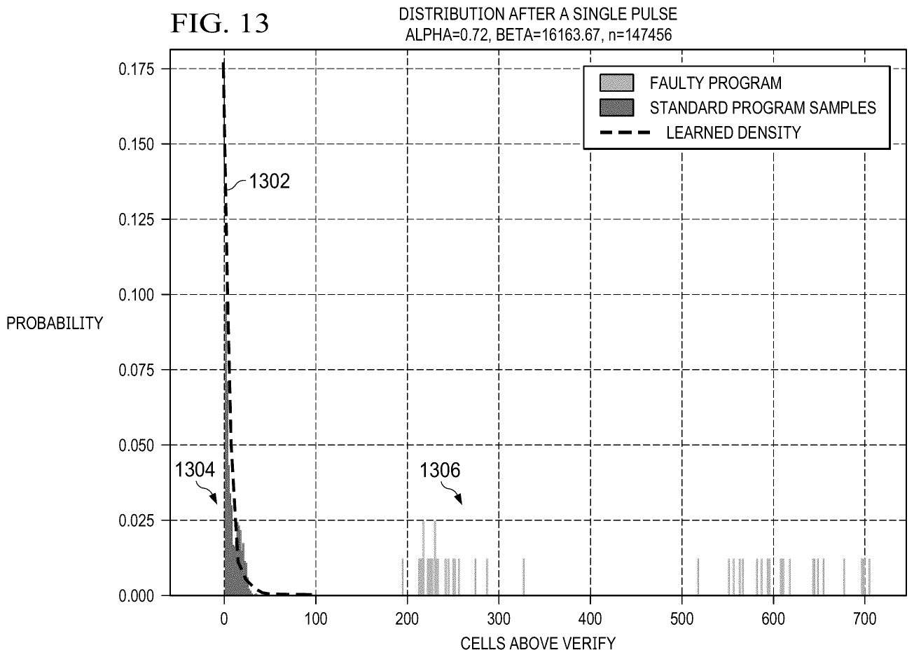

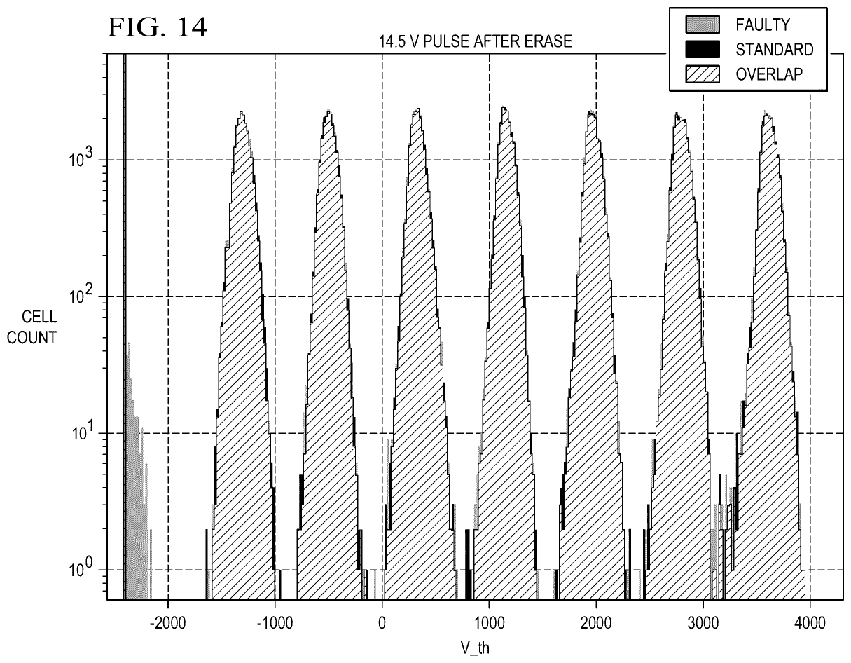

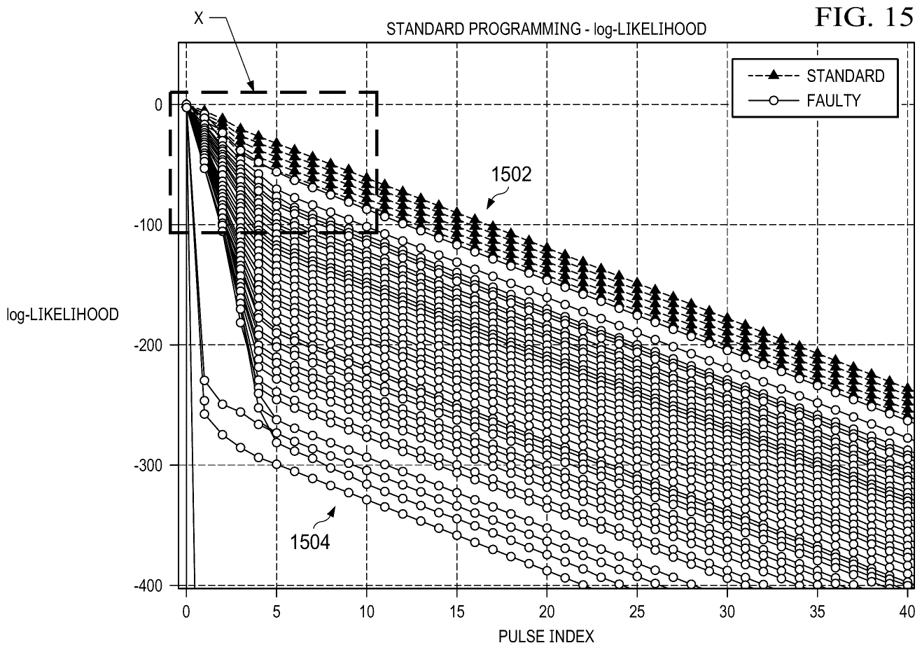

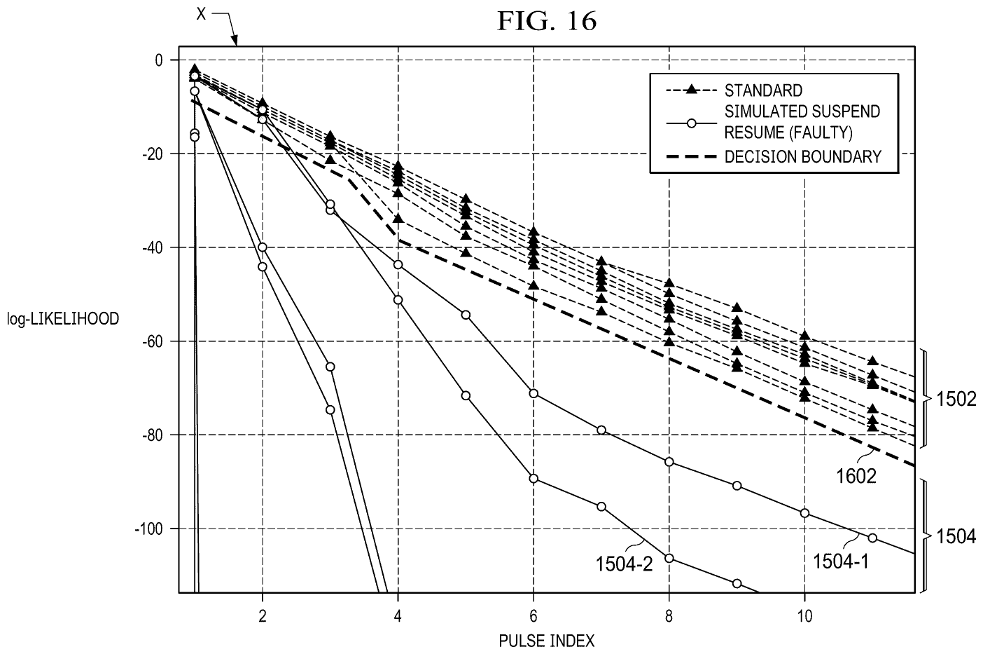

FIG. 12 is a distribution diagram of a faulty iterative programming operation to program a non-volatile memory device, according to some example embodiments. FIG. 13 is a diagram illustrating a probability distribution for verification result values of an n-th programming stage of an iterative programming operation, together with indicators of probability values for n-th programming stage verification result values for both standard sample iterative programming operations and faulty iterative programming operations, according to some example embodiments. FIG. 14 is a distribution diagram of a faulty iterative programming operation to program a non-volatile memory device, according to some example embodiments. FIG. 15 is a line graph illustrating a plurality of probability value sequences determined for separate, respective iterative programming operations, including standard and faulty iterative programming operations, according to some example embodiments. FIG. 16 is an expanded view of region X in FIG. 15 illustrating a threshold value decision boundary dividing probability value sequences determined for separate, respective standard iterative programming operations and probability value sequences determined for separate, respective faulty iterative programming operations, according to some example embodiments. FIGS. 12 and 14 each include at least partial overlap of a distribution diagram of the faulty iterative programming operation and a distribution diagram of a non-faulty (“standard”) iterative programming operation.

The examples illustrated in FIGS. 12 to 14, and in particular as shown by the distribution diagrams of FIGS. 12 and 14, are directed to performing the iterative anomaly detection program 900 to detect at least one programming anomaly in an iterative programming operation that is configured to simulate a programming anomaly (e.g., error) occurring during the suspension of the block-erase-process. As a result of the programming anomaly, the erase process is not completed in the iterative programming operation 800, and majority of the memory cells of the non-volatile memory device remain with a threshold voltage Vth such that a majority of the cells remain with a threshold voltage higher than the erase level (e.g., represented by the portions of FIGS. 12 and 14 showing overlap between the faulty and non-faulty “standard” distribution diagrams). Such an error is simulated by applying a pulse at low voltage on 7/8 of the memory cells connected to a selected word line WL prior to performing the iterative programming operation 800 (e.g., an ISPP scheme) to program the memory cells connected to the selected word line WL. As shown in FIGS. 12 and 14, the memory cells not pre-programmed by the low-voltage-pulse mimic the cells in the erase level before the incomplete erase process (e.g., represented by the portion of the faulty distribution diagram at the far left of each of FIGS. 12 and 14).

In the example shown in FIG. 12, an iterative programming operation 800 is performed on a plurality of memory cells subsequently to applying a 15.5V pulse at low voltage on 7/8 of the memory cells. As a result, and as shown in FIG. 12, at the end of the iterative programming operation 800 the erase level is significantly higher than expected.

Turning to FIG. 13, the iterative anomaly detection program 900 is performed to utilize a first-stage verification result value

$${S}_{1}^{l}$$

for a given verification voltage V^{l} generated at the first programming stage (n=1) of the iterative programming operation 800 that was performed to generate the distribution shown in FIG. 12, where the iterative model 910 of the iterative anomaly detection program 900 is performed based on the first-stage verification result value

$${S}_{1}^{l}$$

and an initialized hidden state value

$${H}_{0}^{l}$$

to determine the probability parameters, or distribution parameters (e.g., Beta-Binomial distribution parameters)

$${α}_{1}^{l} and {β}_{1}^{l}$$

to be 0.782 and 16163.67, respectively. The determined values of

$${α}_{1}^{l} and {β}_{1}^{l}$$

are then used, together with the known number of memory cells connected to the selected word line (N=147456 as shown) to generate a first-stage probability distribution 1302 that is a function of the value of the first-stage verification result value

$${S}_{1}^{l}$$

according to Equation (3) further applied into Equation (2), where the resultant conditional probability at n=1 may be the same as the probability value at stage n=1. As shown, the probability distribution 1302 may indicate a probability that the iterative programming operation for which the probability value is determined does not have any programming anomalies.

FIG. 13 illustrates the probability distribution 1302 learned by the iterative model 910 (e.g., an RNN) for

$${S}_{1}^{1}$$

the number of cells that passed the first verify level after the first ISPP pulse (e.g., the first programming stage PL1). The example shown in FIG. 13 compares the probability distribution 1302 to verification result values

$${S}_{1}^{1}$$

for the simulated faulty iterative programming operation 800 (1306). As shown in the chart in FIG. 13, the iterative model outputs a very low likelihood for the verification result value

$${S}_{1}^{1}$$

for the simulated faulty iterative programming operation 800 (1306), so the simulated faulty iterative programming operation 800 (1306) may be easily identified and classified by the iterative anomaly detection program 900 as including one or more programming anomalies.

As shown in FIG. 13, when at least a first programming stage of the iterative programming operation 800 is performed without simulating the programming anomaly, the resultant probability values 1304 determined based on applying the first-stage verification result values

$${S}_{1}^{l}$$

of such “standard” iterative programming operations to the probability distribution 1302 are generally relatively low (e.g., less than 50) and generally correspond to a probability value, indicated by the probability distribution 1302, of at least 0.001 as shown in FIG. 13.

As further shown in FIG. 13, when at least a first programming stage of the iterative programming operation 800 is performed with the programming anomaly simulated with the 15.5V pulse as described with reference to FIG. 12, the resultant probability values 1306 generally correspond to a probability value, indicated by the probability distribution 1302, of less than about 0.001 as shown in FIG. 13. As further shown, such resultant probability values 1306 may be far beyond a decision boundary indicated by a threshold probability value, for example beyond one or more standard deviations from the mean of the probability distribution 1302. As a result, the resultant probability values 1306 generated from the verification result values of the simulated faulty first programming stage of the iterative programming operation may be determined to indicate the presence of a programming anomaly in the iterative programming operation after as few as a single programming stage (e.g., the first program step and the first verify step), for example due to a determination that the resultant probability value 1306 at least meets a threshold probability value (e.g., is less than 0.001), a threshold variance (e.g., is more than two standard deviations from the mean of the probability distribution 1302), or the like.

As shown in FIG. 13, the iterative anomaly detection program 900, including the iterative model, may detect the programming anomaly corresponding to the improper starting point for the iterative programming operation which leads to an unusual threshold voltage distribution already after the first programming stage PL1 (e.g., the first programming pulse). process FIG. 15 illustrates the distribution learned by the model for

$${S}_{1}^{0} -$$

the number of cells that passed the first verify level after the first ISPP pulse. The iterative anomaly detection program 900 may compare the distribution 1302 tot for

$${S}_{1}^{0}$$

for the faulty program (e.g., 1306). As shown, based on the first programming stage PL1, the iterative model 910 outputs a probability value (1306) (e.g., at S914 in FIG. 10B) indicating a very low likelihood for the faulty iterative programming operations, so such iterative programming operations may be easily classified as faulty (e.g., including at least one programming anomaly), for example based on determining (e.g., at S915 in FIG. 10B) that the programing operations correspond to a probability value that at least meets a threshold probability value (e.g., less than 0.001), a threshold variance (e.g., greater than two standard deviations from the mean), or the like.

Because the simulated programming anomaly can be detected after a single programming stage PL1 by the iterative anomaly detection program 900, the faulty programming operation can be terminated and/or corrected without waiting until completion of the entire programming operation (e.g., eight programming stages). Additionally, programming anomalies other than a low number of cells programmed to at least a particular verify level (verification voltage) may be detected. As a result, a performance speed and a reliability of a device implementing the iterative anomaly detection program 900 may be improved.

Next, as shown in FIG. 14, an iterative programming operation 800 is performed on a plurality of memory cells subsequently to applying a 14.5V pulse at low voltage on 7/8 of the memory cells to mimic the faulty erase scenario. As shown in FIG. 14, the threshold voltage distribution after programming is almost indistinguishable from that of standard (e.g., non-anomalous) iterative programming operations (e.g., represented by the portions of FIG. 14 showing overlap between the faulty and non-faulty “standard” distribution diagrams). However, as shown in FIGS. 15 and 16, the iterative model may be used to clearly distinguish such faulty programming operation from standard (non-anomalous) iterative programming operations.

FIGS. 15 and 16 illustrate operation of the iterative model 910 of the iterative anomaly detection program 900 corresponding to additional programming stages PL (e.g., pulse indexes) of the iterative programming operation 800 represented in FIG. 14 (e.g., the ISPP loop) for at least 40 programming stages (e.g., 40 pulse indexes) and thus 40 corresponding model stages of the iterative model 910, where, for each iterative programming operation 800, the iterative model generates probability values

$${P}_{n}^{l}$$

that indicate the log-likelihood associated with programming anomaly presence for each of the model stages, and each sequence of probability values

$${P}_{1}^{l} , {P}_{2}^{l} , … , {P}_{n}^{l}$$

for each separate iterative programming operation is represented on the line graph as a separate dash line connecting data points representing the probability values (as log-likelihood) generated for the separate iterative programming operation (e.g., based on Equation (2) at each model stage) based on the respective programming stages (e.g., pulse indexes) of the iterative programming operation 800.

The line graphs shown in FIGS. 15-16 illustrate that, over the course of multiple programming stages of the iterative programming operation, the probability value sequences

$$( e . g . , {P}_{1}^{l} , {P}_{2}^{l} , … , {P}_{n}^{l} )$$

of a given faulty iterative programming operation (1504) such as presented by the distribution in FIG. 14 may diverge from probability value sequences (

$$( e . g . , {P}_{1}^{l} , {P}_{2}^{l} , … , {P}_{n}^{l} )$$

of a standard (non-anomalous) iterative programming operation (1502), even if the differences between the faulty and standard iterative programming operations are not immediately apparent in a distribution diagram for the faulty iterative programming operations as shown in FIG. 14.

Still referring to FIG. 16, threshold probability values may be stored (e.g., predetermined) for each of the programming stages (pulse indexes) and a probability value for a given programming stage may be compared with a corresponding threshold probability value for the given programming stage to determine whether the probability value indicates occurrence of at least one programming anomaly in an iterative programming operation. As shown in FIG. 16, the threshold probability values may be presented as a sequence of threshold probability values corresponding to separate programming stages providing a decision boundary 1602, such that the threshold probability values (e.g., expressed as a log-likelihood) to which a given n-th stage probability value

$${P}_{n}^{l}$$

is compared changes with the sequence of programming stages.

The threshold probability value(s) of the decision boundary 1602 may be empirically determined and may be stored in a look-up table, for example a look-up table stored at a memory of a device implementing the iterative anomaly detection program 900. The threshold probability values defining the decision boundary 1602 may be empirically determined to establish the decision boundary 1602 that provides a desirable false positive rate. The anomaly detection program may, in response to determining an n-th probability value corresponding to an n-th programming stage, access the look-up table and determine an n-th threshold probability value also corresponding to the same n-th programming stage, and further determine whether a programming anomaly has occurred in the iterative programming operation 800 based on a determination of whether the n-th probability value at least meets the n-th threshold probability value.

For example, referring to FIG. 16, the probability value sequences 1504-1 and 1504-2, which are each a sequence of probability values

$${P}_{1}^{l} , {P}_{2}^{l} , ... , {P}_{n}^{l}$$

generated by an iterative anomaly detection program 900 corresponding to a simulated faulty iterative programming operation 800 as described with reference to FIG. 14 above, may provide probability values at model stages 1 and 2

$$( {P}_{1}^{l} , {P}_{2}^{l} )$$

that are each a negative log-likelihood that is smaller than the corresponding threshold probability values for model stages 1 and 2 as presented by the decision boundary 1602 at stages (pulse indices) 1 and 2, thereby the iterative anomaly detection program 900 may determine that each of the iterative programming operations represented by sequences 1504-1 and 1504-2 do not have a programming anomaly at model stages 1 and 2, thereby reaching a similar conclusion corresponding to the similarity of the faulty and standard distribution diagrams after the first programming stage as shown in FIG. 14. However, starting at model stage 3 (corresponding to programming stage 3, pulse index 3, etc.) the negative log-likelihoods provided by the respective 3^{rd} stage probability values

$$( {P}_{3}^{l} )$$

of each of the iterative programming operations represented by sequences 1504-1 and 1504-2 are about 30, which is greater in magnitude than the corresponding 3^{rd} stage threshold probability value comprising the decision boundary 1602 at the 3^{rd} model stage with a negative log-likelihood of about 25, such that the iterative anomaly detection program 900 may determine that the respective 3^{rd} stage probability values of each of the iterative programming operations represented by sequences 1504-1 and 1504-2 are greater than the corresponding 3^{rd} stage threshold probability value presented by the decision boundary 1602 at the third stage (third pulse index), such that the iterative anomaly detection program 900 may determine that each of the iterative programming operations represented by sequences 1504-1 and 1504-2 do have at least one programming anomaly at model stage 3, in response to which determination the iterative anomaly detection program 900 may cause a recovery action to be initiated, including for example transmitting a termination command RC1 to cause early termination of the iterative programming operation 800 and/or to perform error correction operations (e.g., marking a bad block, changing addresses, repeating iterative programming operation 800 at the new addresses, etc.).

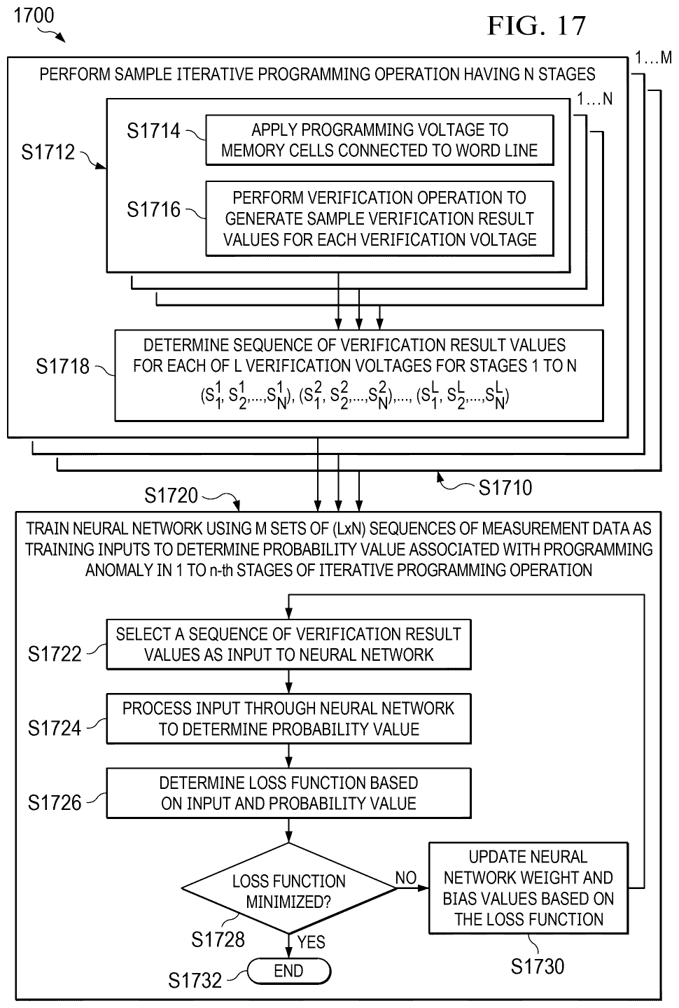

FIG. 17 is a flowchart illustrating a computer-implemented method 1700 of training a neural network, according to some example embodiments. The computer-implemented method 1700 may be a computer-implemented method to determine a probability associated with an occurrence of at least one programming anomaly in an iterative programming operation that programs a non-volatile memory device having a plurality of memory cells connected through a word line, according to some example embodiments.

In some example embodiments, the training includes obtaining measurement data indicating sample verification result values for multiple sample iterative programming operations that do not include any programming anomalies (also referred to herein as “standard” or “non-faulty” iterative programming operations), and then training a neural network (e.g., an RNN) to determine a probability value based on at least some of the sample verification result values, wherein the neural network is trained to either minimize a negative likelihood (e.g., minimize a negative log-likelihood) or maximize a likelihood (e.g., maximize a log-likelihood) indicated by the sample verification result values. Because the sample verification result values correspond to sample iterative programming operations that do not include any programming anomalies, the probability values determined based on applying the sample verification result values to the neural network as inputs may be trained to indicate an absence of programming anomalies in the sample iterative programming operations via determining the probability value as a likelihood (e.g., a log-likelihood) or a negative likelihood (e.g., a negative log-likelihood) that the corresponding iterative programming operation in which the input verification result values are generated does or does not include any programming anomalies.

Referring to FIG. 17, at S1712 the method 1700 includes performing a set of 1 to M, (e.g., one or more) sample iterative programming operations where M is any positive integer. Performing each sample iterative programming operation includes performing a sequence of one or a plurality of programming stages (PL) to program one or more sample non-volatile memory devices. Such sample iterative programming operations may be performed as shown in FIG. 10A for the iterative programming operation 800. For example, as shown, each of the 1 to M sample iterative programming operations may include, for each given n-th programming stage of 1 to N programming stages of the sample iterative programming operation, performing a program operation (e.g., program step) at S1714 to apply a programming voltage Vpgm to memory cells connected to a selected word line of a sample non-volatile memory device (e.g., corresponding to S806 in FIG. 10A) and then, at S1716, performing 1 to L verification operations (e.g., verify step) for each of 1 to L verification voltages to generate 1 to L sample verification result values

$${S}_{n}^{1} , {S}_{n}^{2} , ... , {S}_{n}^{L}$$

for the given n-th programming stage (e.g., corresponding to S808 in FIG. 10A, based on applying verification voltages to the memory cells connected to a selected word line and determining a number of the memory cells having a threshold voltage equal to or greater than a particular one of the verification voltages).

As a result, at S1718, a sequence of sample verification result values are determined (e.g., generated, obtained, etc.) for each of the L verification voltages and for each of the N programming stages, expressed as

$$( {S}_{1}^{1} , {S}_{2}^{1} , ... , {S}_{N}^{1} ) , ( {S}_{1}^{2} , {S}_{2}^{2} , ... , {S}_{N}^{2} ) , ... , ( {S}_{1}^{L} , {S}_{2}^{L} , ... , {S}_{N}^{L} ) ,$$

in each of the 1 to M sample iterative programming operations. The sample verification result values determined at S1718 may be referred to herein as measurement data, sample measurement data, standard measurement data, or the like, where the measurement data includes, for each sample iterative programming operation performed on each sample non-volatile memory device, a sequence of sample verification result values that each indicate a number of memory cells of the sample non-volatile device having a threshold voltage that is equal to or greater than a particular verification voltage at a particular programming stage of the sample iterative programming operation, wherein each sample iterative programming operation of the one or more sample iterative programming operations does not include any programming anomalies.

As further shown in FIG. 17, at S1720 the method 1700 includes training a neural network to determine a probability (e.g., to generate an output that indicates a probability value or may be used to determine a probability value) associated with an occurrence of at least one programming anomaly in an iterative programming operation that programs a non-volatile memory device having a plurality of memory cells connected through a word line. The training at S1720 may be performed based on using (e.g., receiving) some or all of the measurement data (e.g., the sequences of sample verification result values). At S1722, the training may include selecting one of the sequences of sample verification result values determined at S1718

$$( e . g . , {S}_{1}^{1} , {S}_{2}^{1} , ... , {S}_{N}^{1} )$$

as a sequence of inputs to the neural network. The neural network may be an RNN as shown for example in FIG. 9, which may include a sequence of 1 to N RNN cells that are each configured to use one of the 1 to N sample verification result values in the sequence (each sample verification result value indicating a number of memory cells of the plurality of memory cells of the sample non-volatile memory device having a threshold voltage that is equal to or greater than a particular verification voltage of the L verification voltages at a particular one of the N programming stages) as an input and to further utilize historical data associated with a previous programming stage at least an (n−1)-th programming stage of the iterative programming operation (or in the case of the first RNN cell in the sequence, a predetermined zeroth historical data value) to generate output values used to determine probability values corresponding to the sample verification result values. At S1724, the training may include simulating the neural network to determine at least one probability value associated with occurrence of at least one programming anomaly in a sequence of 1 to n-th programming stages of the iterative programming operation based on both an n-th sample verification result value indicating a number of memory cells of the plurality of memory cells having a threshold voltage that is equal to or greater than a particular verification voltage at the n-th programming stage, and n-th historical data associated with at least an (n−1)-th programming stage of the iterative programming operation. In some example embodiments the simulating at S1724 includes performing each of the 1 to N cells (e.g., model stages) of the neural network (e.g., RNN) based on a correspond one of the 1 to N sample verification result values for a particular verification voltage

$$( e . g . , {S}_{1}^{1} , {S}_{2}^{1} , ... , {S}_{N}^{1} ) ,$$

so as to generate a sequence of probability values each corresponding to a separate sample verification result value (e.g., for the final Nth programming stage, a probability value that is a probability

$$P ( {S}_{N}^{1} , {S}_{N - 1}^{1} , ... , {S}_{1}^{1} ) .$$

The determination of probability values at S1724 may be the same as the performing of one or more model stages of an iterative model in the iterative anomaly detection program 900 as shown in FIGS. 9, 10B and/or 11.

At S1726, a log function is determined based on the input (e.g., sample verification result value(s)) used during the simulation at S1724 and the probability value(s) generated as a result of the simulation at S1724. At S1728, a determination is made whether the loss function determined at S1726 is optimized, for example whether the loss function is minimized. If so, at S1730 the neural network is determined to be trained and the training ends. If not, at S1732, one or more of the weight and bias values utilized by the neural network are updated (e.g., incremented by a predetermined magnitude) based on the loss function, and the training is repeated using a new selected sequence of verification result values

$$( e . g . , {S}_{1}^{2} , {S}_{2}^{2} , ... , {S}_{N}^{2} ) .$$

The process then repeats until a determination of S1728=YES.

As noted above, the neural network being trained at S1720 may be a recurrent neural network (RNN). The RNN may be trained to determine the probability value at S1724 as one of a negative likelihood (e.g., a negative log-likelihood) or a likelihood (e.g., a log-likelihood) corresponding to the likelihood or negative likelihood of at least one programming anomaly in the sample iterative programming operation represented by the input verification result value(s). As noted above, the training at S1720 may train the RNN to minimize the negative log-likelihood, or to maximize the log-likelihood.

In some example embodiments, the training at S1720 is performed using backpropagation, for example in example embodiments where the neural network being trained is an RNN. In some example embodiments, the determination of the loss function at S1726 includes a negative log likelihood as shown in Equation (7) below, although example embodiments are not limited thereto:

$$= - log P ( {S}_{n}^{l} \vert {S}_{n - 1}^{l} , ... , {S}_{1}^{l} ) - log P ( {S}_{n - 1}^{l} \vert {S}_{n - 2}^{l} , ... , {S}_{1}^{l} ) ... - log P ( {S}_{1}^{l} ) . \qquad ( 7 )$$

At each stage (e.g., iteration) of the training 1720 and for each set of verification results from the batch (of measurement data), and for example in example embodiments where the neural network determines

$${α}_{n}^{l} , {β}_{n}^{l}$$

values as described above (e.g., based on performing linear transformation of

$${H}_{n}^{l} )$$

the training at S1720 may include: (1) for an n-th programming stage, at S1724, using a selected sequence of sample verification result values

$$( {S}_{n}^{l} , {S}_{n - 1}^{l} , ... {S}_{1}^{l} ) ,$$

to iterate through the RNN to find the corresponding

$${α}_{n}^{l} , {β}_{n}^{l} ,$$

(2) at S1726, calculating the loss function using

$$( {S}_{n}^{l} , {S}_{n - 1}^{l} , ... {S}_{1}^{l} ) and {α}_{n}^{l} , {β}_{n}^{l}$$

in Equation (7) above, and (3) updating the weights and biases of the RNN via backpropagation (e.g., via known backpropagation processes) at S1728, S1730, and/or S1732.

Once the neural network is determined to be trained (e.g., the loss function is determined to be minimized at S1728=YES), the neural network may be applied to a device according to any of the example embodiments to be used in an iterative anomaly detection program. For example, the updated weights and biases of the trained neural network may be applied to an RNN of a device according to any of the example embodiments to configure the device to utilize the trained RNN as the iterative model of the iterative anomaly detection program 900 to determine a probability associated with occurrence of at least one programming anomaly in an iterative programming operation.

FIG. 18 is a schematic block diagram of an electronic device according to some example embodiments.

Referring to FIG. 18, an electronic device 2000 in accordance with some example embodiments may include a microprocessor 2010, a memory 2020, and a user interface 2030 that perform data communication using a bus 2040. The microprocessor 2010 may include a central processing unit (CPU) or an application processor (AP). The electronic device 2000 may further include a random access memory (RAM) 2050 in direct communication with the microprocessor 2010. The microprocessor 2010 and/or the RAM 2050 may be implemented in a single module or package. The user interface 2030 may be used to input data to the electronic device 2000, or output data from the electronic device 2000. For example, the user interface 2030 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 2020 may store operational codes of the microprocessor 2010, data processed by the microprocessor 2010, or data received from an external device. The memory 2020 may include a memory controller, a hard disk, or a solid state drive (SSD).

As described herein, any devices, systems, modules, portions, units, controllers, circuits, and/or portions thereof according to any of the example embodiments, and/or any portions thereof (including, without limitation, the system 1000, the main processor 1100, the memory 1200a, the memory 1200b, the storage device 1300a, the storage controller 1310a, the NVM 1320a, the storage device 1300b, the storage controller 1310b, the NVM 1320b, the storage device 200, the storage controller 210, the NVM 220, the storage device 15, the memory controller 16, the memory device 17, the memory device 300, the memory interface circuitry 310, the control logic circuitry 320, the memory cell array 330, the page buffer 340, the voltage generator 350, the row decoder 360, the memory device 600, the electronic device 2000, the microprocessor 2010, the memory 2020, the RAM 2050, the user interface 2030, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage medium (e.g., a memory, for example the memory 2020 in the electronic device 2000 in FIG. 18), for example a solid state drive (SSD), storing a program of instructions, and a processor (e.g., CPU, for example for example the microprocessor 2010 in the electronic device 2000 in FIG. 18) configured to execute the program of instructions to implement the functionality and/or methods performed by some or all of any devices, systems, modules, portions, units, controllers, circuits, and/or portions thereof according to any of the example embodiments, including performing any of the methods according to any of the example embodiments, including for example an iterative programming operation to program a non-volatile memory device having at least a plurality of memory cells, where the plurality of memory cells are connected through a word line according to any of the example embodiments, an iterative anomaly detection program according to any of the example embodiments, a neural network training operation according to any of the example embodiments, any combination thereof, or the like.

It will be understood that, in some example embodiments, a non-transitory computer readable storage medium (e.g., a SSD storage device) may be provided, where the non-transitory computer readable storage medium is storing a program of instructions that, when executed by at least one processor, is configured to cause the at least one processor to perform any of the methods according to any of the example embodiments, including for example an iterative programming operation to program a non-volatile memory device having at least a plurality of memory cells, where the plurality of memory cells are connected through a word line according to any of the example embodiments, an iterative anomaly detection program according to any of the example embodiments, a neural network training operation according to any of the example embodiments, any combination thereof, or the like. Such a non-transitory computer readable storage medium may be provided independently or may be included in another device (e.g., an electronic device, such as in the memory 2020 in the electronic device 2000 in FIG. 18).

While the inventive concepts have been described with reference to some example embodiments thereof, it will be apparent to those of ordinary skill in the art that various changes and modifications may be made thereto without departing from the spirit and scope of the inventive concepts as set forth in the following claims.

1. A method, comprising:
performing an iterative programming operation to program a non-volatile memory device having at least a plurality of memory cells, where the plurality of memory cells are connected through a word line, the iterative programming operation having a sequence of at least 1 to n-th programming stages, n being a positive integer that is greater than 1, the n-th programming stage includes,
applying an n-th program voltage to the word line connected to the plurality of memory cells, and
performing a verification operation associated with a particular verification voltage on the plurality of memory cells to generate an n-th verification result value, the n-th verification result value indicating a number of memory cells of the plurality of memory cells having a threshold voltage that is equal to or greater than the particular verification voltage at the n-th programming stage; and
performing at least an n-th model stage of an iterative model that utilizes the n-th verification result value and n-th historical data associated with at least an (n−1)-th programming stage of the iterative programming operation to determine an n-th probability value indicating a probability associated with occurrence of at least one programming anomaly in the 1 to n-th programming stages of the iterative programming operation.

2. The method of claim 1, further comprising:
performing a plurality of verification operations on the plurality of memory cells to generate a plurality of n-th verification result values, wherein
the plurality of verification operations include the verification operation,
the plurality of verification operations are associated with separate, respective verification voltages of a plurality of verification voltages that are different from each other,
the plurality of n-th verification result values include the n-th verification result value, and
each separate n-th verification result value of the plurality of n-th verification result values indicates a separate number of memory cells of the plurality of memory cells having a threshold voltage that is equal to or greater than a separate verification voltage of the plurality of verification voltages at the n-th programming stage; and
performing an n-th model stage of one or more iterative models that utilize the plurality of n-th verification result values and historical data associated with at least the (n−1)-th programming stage of the iterative programming operation to determine a plurality of n-th probability values, wherein
the plurality of n-th probability values include the n-th probability value,
each separate n-th probability value is determined based on applying a separate n-th verification result of the plurality of n-th verification result values to the one or more iterative models, and
each separate n-th probability value of the plurality of n-th probability values indicates a separate probability associated with occurrence of at least one programming anomaly in the 1 to n-th programming stages of the iterative programming operation.

3. The method of claim 2, further comprising:
determining that the at least one programming anomaly has occurred in the 1 to n-th programming stages of the iterative programming operation based on determining that at least one n-th probability value of the plurality of n-th probability values at least meets a corresponding n-th threshold probability value.

4. The method of claim 2, wherein the performing the n-th model stage of the one or more iterative models includes
performing an n-th model stage of each separate iterative model of a plurality of iterative models that each generate a separate n-th probability value of the plurality of n-th probability values, wherein each n-th model stage of each separate iterative model utilizes a separate n-th verification result value of the plurality of n-th verification result values that is associated with a particular verification voltage of the plurality of verification voltages and separate historical data associated with the particular verification voltage in at least the (n−1)-th programming stage of the iterative programming operation, or
performing a single iterative model that generates the plurality of n-th probability values based on utilizing the plurality of n-th verification result values and historical data associated with the plurality of verification voltages in at least the (n−1)-th programming stage of the iterative programming operation.

5. (canceled)

6. The method of claim 1, further comprising:
determining that the at least one programming anomaly has occurred in the 1 to n-th programming stages of the iterative programming operation based on determining that the n-th probability value at least meets an n-th threshold probability value.

7. The method of claim 6, further comprising causing a recovery action to be performed in response to determining that the at least one programming anomaly has occurred in the 1 to n-th programming stages of the iterative programming operation, the recovery action including at least one of
an error correction operation,
terminating the iterative programming operation prior to completion of a final programming stage of the iterative programming operation, or
transmitting a warning signal to provide an indication of the occurrence of the at least one programming anomaly.

8. (canceled)

9. The method of claim 1, wherein the n-th model stage of the iterative model is performed at least partially concurrently with performing an (n+1)-th programming stage of the iterative programming operation at an (n+1)-th time step.

10. The method of claim 1, wherein the determining the n-th probability value includes
determining an n-th conditional probability distribution based on performing at least the n-th model stage of the iterative model, the n-th conditional probability distribution indicating a distribution of probability values corresponding to verification result values, and
determining a probability value indicated by the n-th conditional probability distribution that corresponds to the n-th verification result value as the n-th probability value.

11. (canceled)

12. (canceled)

13. (canceled)

14. (canceled)

15. The method of claim 1, wherein
the iterative programming operation includes N total stages, n being less than N, and
the method further includes determining that the at least one programming anomaly has occurred in the 1 to n-th programming stages of the iterative programming operation prior to completion of an N-th programming stage of the iterative programming operation.

16. The method of claim 15, further comprising causing a recovery action to be performed in response to determining that the at least one programming anomaly has occurred in the 1 to n-th programming stages of the iterative programming operation, such that the recovery action is performed prior to completion of the N-th programming stage of the iterative programming operation, the recovery action including at least one of an error correction operation,
terminating the iterative programming operation, or
transmitting a warning signal to provide an indication of the occurrence of the at least one programming anomaly.

17. (canceled)

18. (canceled)

19. (canceled)

20. (canceled)

21. (canceled)

22. A storage device, comprising:
a non-volatile memory device having at least a plurality of memory cells, where the plurality of memory cells are connected through a word line; and
a processor configured to
perform an iterative programming operation to program the non-volatile memory device, the iterative programming operation having a sequence of at least 1 to n-th programming stages, n being a positive integer that is greater than 1, the n-th programming stage includes,
applying an n-th program voltage to the word line connected to the plurality of memory cells, and
performing a verification operation associated with a particular verification voltage on the plurality of memory cells to generate an n-th verification result value, the n-th verification result value indicating a number of memory cells of the plurality of memory cells having a threshold voltage that is equal to or greater than the particular verification voltage at the n-th programming stage, and
perform at least an n-th model stage of an iterative model that utilizes the n-th verification result value and n-th historical data associated with at least an (n−1)-th programming stage of the iterative programming operation to determine an n-th probability value indicating a probability associated with occurrence of at least one programming anomaly in the 1 to n-th programming stages of the iterative programming operation.

23. The storage device of claim 22, the processor further configured to execute the program of instructions to
perform a plurality of verification operations on the plurality of memory cells to generate a plurality of n-th verification result values, wherein
the plurality of verification operations include the verification operation,
the plurality of verification operations are associated with separate, respective verification voltages of a plurality of verification voltages that are different from each other,
the plurality of n-th verification result values include the n-the verification result value, and
each separate n-th verification result value of the plurality of n-th verification result values indicates a separate number of memory cells of the plurality of memory cells having a threshold voltage that is equal to or greater than a separate verification voltage of the plurality of verification voltages at the n-th programming stage, and
perform an n-th model stage of one or more iterative models that utilize the plurality of n-th verification result values and historical data associated with at least the (n−1)-th programming stage of the iterative programming operation to determine a plurality of n-th probability values, wherein
the plurality of n-th probability values include the n-th probability value,
each separate n-th probability value is determined based on applying a separate n-th verification result of the plurality of n-th verification result values to the one or more iterative models, and
each separate n-th probability value of the plurality of n-th probability values indicates a separate probability associated with occurrence of at least one programming anomaly in the 1 to n-th programming stages of the iterative programming operation.

24. The storage device of claim 23, the processor further configured to execute the program of instructions to
determine that the at least one programming anomaly has occurred in the 1 to n-th programming stages of the iterative programming operation based on determining that at least one n-th probability value of the plurality of n-th probability values at least meets a corresponding n-th threshold probability value.

25. The storage device of claim 23, wherein the performing the n-th model stage of the one or more iterative models includes
performing an n-th model stage of each separate iterative model of a plurality of iterative models that each generate a separate n-th probability value of the plurality of n-th probability values, wherein each n-th model stage of each separate iterative model utilizes a separate n-th verification result value of the plurality of n-th verification result values that is associated with a particular verification voltage of the plurality of verification voltages and separate historical data associated with the particular verification voltage in at least the (n−1)-th programming stage of the iterative programming operation, or
performing a single iterative model that generates the plurality of n-th probability values based on utilizing the plurality of n-th verification result values and historical data associated with the plurality of verification voltages in at least the (n−1)-th programming stage of the iterative programming operation.

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. An electronic device, comprising:
the storage device of claim 22; and
a control circuit configured to communicate with the storage device to cause data to be written to the storage device and/or to be read from the storage device.

41. (canceled)

42. (canceled)

43. A non-transitory computer-readable storage medium having a computer program recorded thereon, the computer program, when executed by at least one processor, is configured to cause the at least one processor to perform a method, the method comprising:
performing an iterative programming operation to program a non-volatile memory device having at least a plurality of memory cells, where the plurality of memory cells are connected through a word line, the iterative programming operation having a sequence of at least 1 to n-th programming stages, n being a positive integer that is greater than 1, the n-th programming stage includes,
applying an n-th program voltage to the word line connected to the plurality of memory cells, and
performing a verification operation associated with a particular verification voltage on the plurality of memory cells to generate an n-th verification result value, the n-th verification result value indicating a number of memory cells of the plurality of memory cells having a threshold voltage that is equal to or greater than the particular verification voltage at the n-th programming stage; and
performing at least an n-th model stage of an iterative model that utilizes the n-th verification result value and n-th historical data associated with at least an (n−1)-th programming stage of the iterative programming operation to determine an n-th probability value indicating a probability associated with occurrence of at least one programming anomaly in the 1 to n-th programming stages of the iterative programming operation.

44. The non-transitory computer-readable storage medium of claim 43, the method further comprising:
performing a plurality of verification operations on the plurality of memory cells to generate a plurality of n-th verification result values, wherein
the plurality of verification operations include the verification operation,
the plurality of verification operations are associated with separate, respective verification voltages of a plurality of verification voltages that are different from each other,
the plurality of n-th verification result values include the n-the verification result value, and
each separate n-th verification result value of the plurality of n-th verification result values indicates a separate number of memory cells of the plurality of memory cells having a threshold voltage that is equal to or greater than a separate verification voltage of the plurality of verification voltages at the n-th programming stage; and
performing an n-th model stage of one or more iterative models that utilize the plurality of n-th verification result values and historical data associated with at least the (n−1)-th programming stage of the iterative programming operation to determine a plurality of n-th probability values, wherein
the plurality of n-th probability values include the n-th probability value,
each separate n-th probability value is determined based on applying a separate n-th verification result of the plurality of n-th verification result values to the one or more iterative models, and
each separate n-th probability value of the plurality of n-th probability values indicates a separate probability associated with occurrence of at least one programming anomaly in the 1 to n-th programming stages of the iterative programming operation.

45. The non-transitory computer-readable storage medium of claim 44, the method further comprising:
determining that the at least one programming anomaly has occurred in the 1 to n-th programming stages of the iterative programming operation based on determining that at least one n-th probability value of the plurality of n-th probability values at least meets a corresponding n-th threshold probability value.

46. The non-transitory computer-readable storage medium of claim 44, wherein the performing the n-th model stage of the one or more iterative models includes
performing an n-th model stage of each separate iterative model of a plurality of iterative models that each generate a separate n-th probability value of the plurality of n-th probability values, wherein each n-th model stage of each separate iterative model utilizes a separate n-th verification result value of the plurality of n-th verification result values that is associated with a particular verification voltage of the plurality of verification voltages and separate historical data associated with the particular verification voltage in at least the (n−1)-th programming stage of the iterative programming operation, or
performing a single iterative model that generates the plurality of n-th probability values based on utilizing the plurality of n-th verification result values and historical data associated with the plurality of verification voltages in at least the (n−1)-th programming stage of the iterative programming operation.

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)

61. An electronic device, comprising:
the non-transitory computer-readable storage medium of claim 43; and
a processor configured to execute the computer program recorded on the non-transitory computer-readable storage medium to perform the method.

62. (canceled)

63. (canceled)
